(19) United States
(12) Patent Application Publication
(10) Pub. No.: US 2021/0082864 A1
(43) Pub. Date: Mar. 18, 2021

(54) SEMICONDUCTOR INTEGRATED CIRCUIT AND RECEIVING DEVICE

(71) Applicant: Kioxia Corporation, Minato-ku (JP)

(72) Inventor: Yuji SATOH, Kawasaki (JP)

(73) Assignee: Kioxia Corporation, Minato-ku (JP)

(21) Appl. No.: 16/816,697

(22) Filed: Mar. 12, 2020

(30) Foreign Application Priority Data
Sep. 13, 2019 (JP) 2019-167672

(51) Int. Cl. H01L 23/00

(52) U.S. Cl. CPC H01L 24/75; H01L 2924/14; H01L 24/81

(57) ABSTRACT

According to one embodiment, there is provided a semiconductor integrated circuit including a first line, a second line, a third line, a fourth line, a latch circuit, a first offset adjustment circuit, and a second offset adjustment circuit. The second line forms a differential pair with the first line. The fourth line forms a differential pair with the third line. The latch circuit has a first input node, a second input node, a first output node, and a second output node. The first input node is electrically connected to the first line. The second input node is electrically connected to the second line. The first output node is electrically connected to the third line. The second output node is electrically connected to the fourth line. The first offset adjustment circuit is electrically connected between the first line and the third line. The second offset adjustment circuit has a circuit configuration equivalent to the first offset adjustment circuit. The second offset adjustment circuit is electrically connected between the second line and the fourth line.

### CROSS-REFERENCE TO RELATED APPLICATIONS

This application is based upon and claims the benefit of priority from Japanese Patent Application No. 2019-167672, filed on Sep. 13, 2019; the entire contents of which are incorporated herein by reference.

### FIELD

Embodiments described herein relate generally to a semiconductor integrated circuit and a receiving device.

### BACKGROUND

A semiconductor integrated circuit having a circuit of differential configuration for processing a pair of differential signals is known. In this circuit, it is desired that the pair of differential signals is appropriate.

### BRIEF DESCRIPTION OF THE DRAWINGS

FIG. 1 is a diagram illustrating a configuration of a communication system to which a semiconductor integrated circuit according to an embodiment is applied;

FIG. 2 is a circuit diagram illustrating a configuration of an edge sampler in the embodiment;

FIG. 3 is a circuit diagram illustrating a configuration of a comparator in the embodiment;

FIG. 4 is a diagram illustrating operations of a latch circuit and offset adjustment circuits in the embodiment;

FIGS. 5A to 5D are diagrams for explaining an operation of the comparator in the embodiment;

FIG. 6 is a circuit diagram illustrating a configuration of an edge sampler in a first modification example of the embodiment;

FIG. 7 is a circuit diagram illustrating a configuration of a comparator in the first modification example of the embodiment;

FIG. 8 is a diagram illustrating operations of a latch circuit and offset adjustment circuits in the first modification example of the embodiment;

FIG. 9 is a circuit diagram illustrating a configuration of an edge sampler in a second modification example of the embodiment;

FIG. 10 is a diagram illustrating operations of a latch circuit and offset adjustment circuits in the second modification example of the embodiment;

FIG. 11 is a circuit diagram illustrating a configuration of an edge sampler in a third modification example of the embodiment;

FIG. 12 is a circuit diagram illustrating a configuration of an edge sampler in a fourth modification example of the embodiment;

FIG. 13 is a circuit diagram illustrating a configuration of an edge sampler in a fifth modification example of the embodiment;

FIG. 14 is a circuit diagram illustrating a configuration of an edge sampler in a sixth modification example of the embodiment;

FIG. 15 is a circuit diagram illustrating a configuration of an edge sampler in a seventh modification example of the embodiment;

FIG. 16 is a circuit diagram illustrating a configuration of an edge sampler in an eighth modification example of the embodiment;

FIG. 17 is a diagram illustrating a configuration of another semiconductor integrated circuit (successive approximation AD conversion circuit) to which the latch circuit and the offset adjustment circuits in the embodiment and the first to eighth modification examples of the embodiment are applied; and

FIG. 18 is a diagram illustrating a configuration of still another semiconductor integrated circuit (flash AD conversion circuit) to which the latch circuit and the offset adjustment circuits in the embodiment and the first to eighth modification examples of the embodiment are applied.

### DETAILED DESCRIPTION

In general, according to one embodiment, there is provided a semiconductor integrated circuit including a first line, a second line, a third line, a fourth line, a latch circuit, a first offset adjustment circuit, and a second offset adjustment circuit. The second line forms a differential pair with the first line. The fourth line forms a differential pair with the third line. The latch circuit has a first input node, a second input node, a first output node, and a second output node. The first input node is electrically connected to the first line. The second input node is electrically connected to the second line. The first output node is electrically connected to the third line. The second output node is electrically connected to the fourth line. The first offset adjustment circuit is electrically connected between the first line and the third line. The second offset adjustment circuit has a circuit configuration equivalent to the first offset adjustment circuit. The second offset adjustment circuit is electrically connected between the second line and the fourth line.

Exemplary embodiments of a semiconductor integrated circuit will be explained below in detail with reference to the accompanying drawings. The present invention is not limited to the following embodiments.

### Embodiment

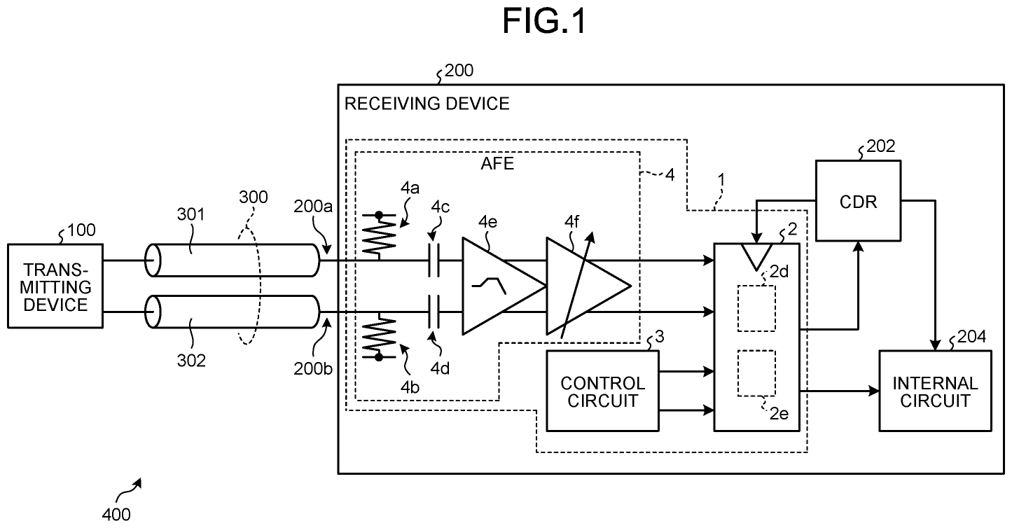

A semiconductor integrated circuit 1 according to an embodiment can be used, for example, in a communication system 400 that performs wired communication. For example, the communication system 400 to which the semiconductor integrated circuit 1 is applied is configured as illustrated in FIG. 1. FIG. 1 is a diagram illustrating the configuration of the communication system 400 to which the semiconductor integrated circuit 1 according to the embodiment is applied.

The communication system 400 includes a transmitting device 100, a receiving device 200, and a wired communication path 300. The transmitting device 100 and the receiving device 200 are communicably connected via the wired communication path 300. The transmitting device 100 transmits data signal to the receiving device 200 via the wired communication path 300. The wired communication path 300 is configured differentially, and includes a P-side communication path 301 and an N-side communication path 302. The receiving device 200 receives differential data signal from the transmitting device 100 via the wired communication path 300. The receiving device 200 includes receiving nodes 200a and 200b, the semiconductor integrated circuit 1, a clock data recovery (CDR) circuit 202, and an internal circuit 204. The wired communication path 300 can be connected to the receiving nodes 200a and 200b. The semiconductor integrated circuit 1 is disposed on the output side of the receiving nodes 200a and 200b.

It should be noted that a modulation method used in this wired communication is amplitude modulation, and may be, for example, a binary modulation method such as NRZ, or a multi-level amplitude modulation method in which multi-level data are mapped in an amplitude direction (for example, a 4-level pulse amplitude modulation method (PAM4)). In a following explanation, a case of the binary modulation method will be described, but the present embodiment can be similarly applied to the multi-level amplitude modulation method. Further, the modulation method can be similarly applied not only to amplitude modulation but also to phase modulation.

The semiconductor integrated circuit 1 includes an analog front end (AFE) 4, a sampler circuit 2, and a control circuit 3.

The AFE 4 is electrically connected to the receiving nodes 200a and 200b and functions as a receiving circuit. The AFE 4 includes pull-up resistors 4a and 4b, coupling capacitors 4c and 4d, an equalization circuit 4e, and a driver 4f. The equalization circuit 4e performs continuous time linear equalizer (CTLE) processing, and performs signal equalization with a gain characteristic corresponding to an inverse characteristic of an attenuation characteristic of the wired communication path 300, for example. The driver 4f drives the equalized signal and transmits the signal to the sampler circuit 2.

The sampler circuit 2 receives a differential signal from the AFE 4, receives a control signal from the control circuit 3, and receives a clock from the CDR circuit 202. The sampler circuit 2 performs sampling of data signal corresponding to the received signal by using the control signal in synchronization with the clock from the CDR circuit 202, and supplies the sampling result to the CDR 202 and the internal circuit 204. For example, the sampler circuit 2 includes a data sampler 2d and an edge sampler 2e. The data sampler 2d samples data portions of the data signal. The edge sampler 2e samples edge portions of the data signal. Each of the data sampler 2d and the edge sampler 2e can be composed of a comparator that compares a potential of the data signal with a potential of the reference signal. Each of the data sampler 2d and the edge sampler 2e can output an H level signal or an L level signal as a comparison result.

Here, since a sampling result of the edge sampler 2e (for example, the comparison result of the comparator) is supplied to the CDR 202 and is used for a determination of the leading or lagging phase in a phase adjustment of the CDR 202, temporal accuracy may be required. In the comparator used in the edge sampler 2e, when a potential of an input signal is near the potential of the reference signal, the comparison result thereof may be an indefinite value in which the reliability of the comparison result does not satisfy a required level, such as dragging a previous comparison result as a history, for example. A potential range of the input signal in which the comparison result of the comparator is an indefinite value is referred to as an indefinite interval, and maintaining an immediately preceding comparison result by the comparator performing a comparison operation in the indefinite interval may be referred to as a hysteresis of the comparator.

A sampling of the edge portion is a sampling during the potential level of the data signal is transiting. That is, the edge sampler 2e compares a potential of the edge portion of the data signal with a potential of a reference signal close to the potential of the edge portion. For example, in a case where the reference potential of the comparator and the potential of the input signal are almost equal and the indefinite interval of the comparator is wide, when the CDR 202 is locked using the comparison result of the comparator, a jitter of the clock recovered by the CDR circuit 202 may increase. In order to reduce the jitter of the clock recovered by the CDR circuit 202, it is desired to shorten the indefinite interval in the comparison operation of the comparator and relax the hysteresis of the comparator.

On the other hand, as a result of investigation, it has been found that the hysteresis of the comparator is caused by holding the previous history in the latch circuit on an output side of the comparator. The comparator should originally have no hysteresis, but acts to have the hysteresis by operating the latch circuit that holds the previous history as a load.

As a result of further investigation, it has been found that the hysteresis of the comparator is caused by a transfer of charge to the comparator through a parasitic coupling capacitance between an input node and an output node of the latch circuit during the sampling period. That is, when unbalanced offset components due to the parasitic coupling capacitance exist between differential pairs from differential output nodes of the latch circuit to differential input nodes of the latch circuit, the offset components occur in the differential output nodes of the comparator. Due to the offset component, the threshold value of the sampling of the comparator (that is, comparison operation) may equivalently vary from an appropriate level potential of the reference signal). Thereby, the indefinite interval of the comparison operation of the comparator may be increased. That is, the comparator may have a remarkable hysteresis.

Therefore, in the present embodiment, in the edge sampler 2e, by adding an offset adjustment circuit for each of a differential pairs between input nodes and output nodes of the latch circuit, and equalizing the offset components occurring at the input nodes between the differential pairs, the pair of differential signals is optimized.

Specifically, in the edge sampler 2e, a P-side offset adjustment circuit is electrically connected between a P-side input node and a P-side output node of the differential pair of the latch circuit, and an N-side offset adjustment circuit is electrically connected between an N-side input node and an N-side output node of the differential pair thereof. The P-side offset adjustment circuit and the N-side offset adjustment circuit have an equivalent circuit configuration. That is, the latch circuit includes a plurality of logic gates having an equivalent configuration, and each of the P-side offset adjustment circuit and the N-side offset adjustment circuit can be configured by a logic gate having a configuration equivalent to the logic gate in the latch circuit. In the P-side offset adjustment circuit, a level corresponding to the result of logical operation of the level of the P-side input node and the level of the P-side output node appears at a floating node on the output side (P-side floating node). In the N-side offset adjustment circuit, a level corresponding to the result of logical operation of the level of the N-side input node and the level of the N-side output node appears at the output node (N-side floating node). Thereby, since the pair of differential signals (that is, the P-side signal and the N-side signal) can be optimized, and equal offset components can appear between the differential pairs in the differential output node of the comparator, the offset components can be canceled differentially in the comparator. As a result, the indefinite interval of the comparison operation of the comparator can be decreased. That is, the hysteresis of the comparator can be relaxed.

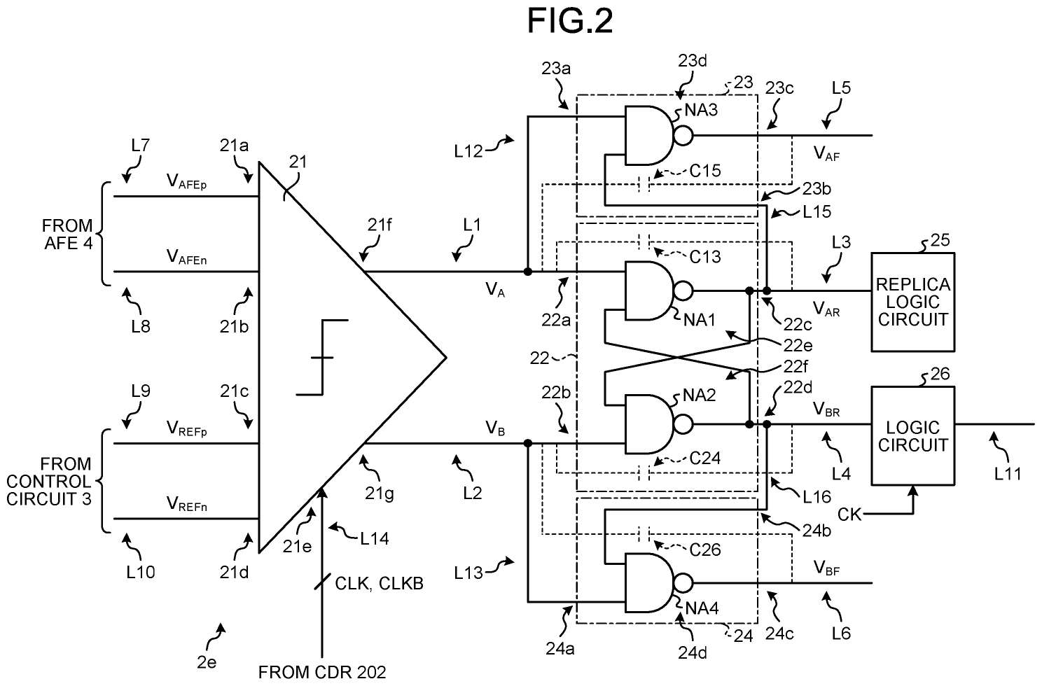

More specifically, the edge sampler 2e can be configured as illustrated in FIG. 2. FIG. 2 is a circuit diagram illustrating the configuration of the edge sampler 2e.

The edge sampler 2e includes lines L1 to L16, a comparator 21, a latch circuit 22, an offset adjustment circuit 23, an offset adjustment circuit 24, a replica logic circuit 25, and a logic circuit 26.

The line L1 is electrically connected between the comparator 21, and the latch circuit 22 and the offset adjustment circuit 23. The line L2 is electrically connected between the comparator 21, and the latch circuit 22 and the offset adjustment circuit 24. The line L3 is electrically connected between the latch circuit 22 and the offset adjustment circuit 23, and the replica logic circuit 25. The line L4 is electrically connected between the latch circuit 22 and the offset adjustment circuit 24, and the logic circuit 26. The line L5 is electrically connected to the offset adjustment circuit 23. The line L5 is not directly connected to the lines L1 and L3. The line L6 is electrically connected to the offset adjustment circuit 24. The line L6 is not directly connected to the lines L2 and L4. The lines L5 and L6 each are in an open state that is not connected to any of the lines L1 to L4. The lines L7 and L8 each are electrically connected between the AFE 4 and the comparator 21. The lines L9 and L10 each are electrically connected between the control circuit 3 and the comparator 21. The line L11 is electrically connected between the logic circuit 26 and the CDR 202, and the internal circuit 204 (see FIG. 1). The line L12 is electrically connected between the line L1 and the offset adjustment circuit 23. The line L13 is electrically connected between the line L2 and the offset adjustment circuit 24. The line L14 is electrically connected between the CDR 202 and the comparator 21. The line L15 is electrically connected between the latch circuit 22 and the offset adjustment circuit 23. The line L16 is electrically connected between the latch circuit 22 and the offset adjustment circuit 24.

The line L1 and the line L2 form a differential pair with each other. The line L3 and the line L4 form a differential pair with each other. The line L7 and the line L8 form a differential pair with each other. The line L9 and the line L10 form a differential pair with each other.

The comparator 21 is disposed between the AFE 4 and the control circuit 3, and the latch circuit 22, the offset adjustment circuit 23, and the offset adjustment circuit 24. The comparator 21 includes an input node 21a, an input node 21b, an input node 21c, an input node 21d, an input node 21e, an output node 21f, and an output node 21g.

The input node 21a is a P-side input node, and the P-side line L7 is electrically connected thereto. The input node 21a is electrically connected to the AFE 4 via the line L7, and receives a P-side data signal V_{AFEp} from the AFE 4 via the line L7.

The input node 21b is an N-side input node, and the N-side line L8 is electrically connected thereto. The input node 21b is electrically connected to the AFE 4 via the line L8, and receives an N-side data signal V_{AFEn} from the AFE 4 via the line L8.

The input node 21c is a P-side reference input node, and the P-side line L9 is electrically connected thereto. The input node 21c is electrically connected to the control circuit 3 via the line L9, and receives a P-side reference signal V_{REFp} from the control circuit 3 via the line L9.

The input node 21d is an N-side reference input node, and the N-side line L10 is electrically connected thereto. The input node 21d is electrically connected to the control circuit 3 via the line L10, and receives an N-side reference signal V_{REFn} from the control circuit 3 via the line L10.

The input node 21e is a clock input node, and the line L14 is electrically connected thereto. The input node 21e is electrically connected to the CDR 202 via the line L14, and receives a clock signal CLK from the CDR 202 via the line L14.

The output node 21f is a P-side output node, and the P-side lines L1 and L12 are electrically connected thereto. The output node 21f is electrically connected to the latch circuit 22 via the line L1, and supplies a P-side signal V_{A} as a comparison result to the latch circuit 22 via the line L1. The output node 21f is electrically connected to the offset adjustment circuit 23 via the line L1 and the line L12, and supplies the P-side signal V_{A} as a comparison result to the offset adjustment circuit 23 via the line L1 and the line L12.

The output node 21g is an N-side output node, and the N-side lines L2 and L13 are electrically connected thereto. The output node 21g is electrically connected to the latch circuit 22 via the line L2, and supplies an N-side signal V_{B} as a comparison result to the latch circuit 22 via the line L2. The output node 21g is electrically connected to the offset adjustment circuit 24 via the line L2 and the line L13, and supplies the N-side signal V_{B} as a comparison result to the offset adjustment circuit 24 via the line L2 and the line L13.

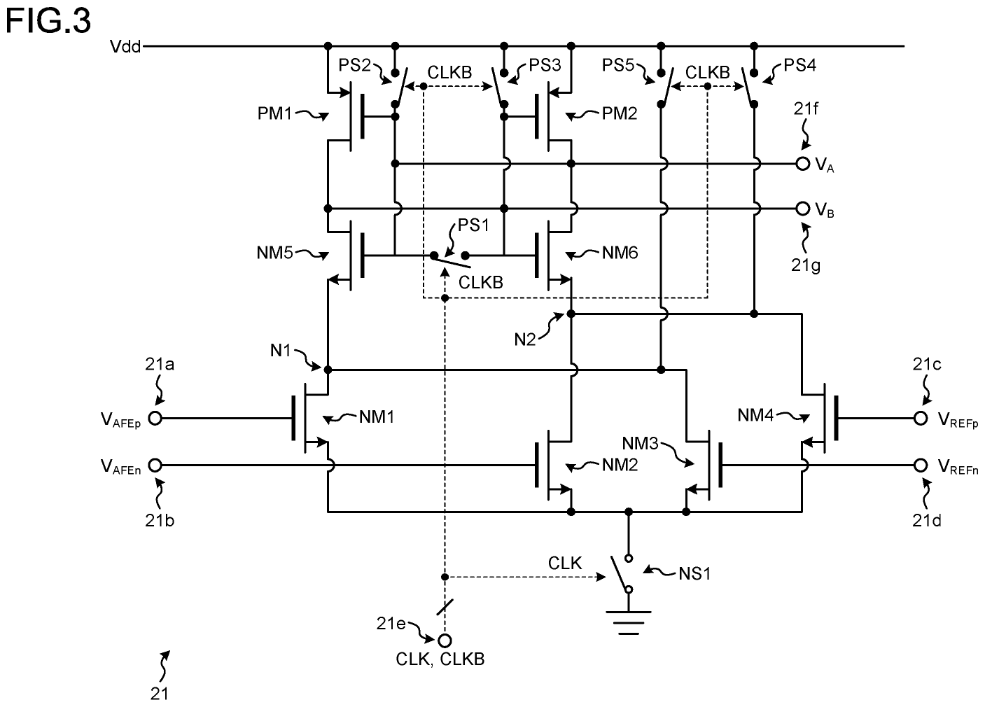

For example, the comparator 21 is an H reset (high reset) comparator. The comparator 21 performs a reset operation in the period in which the clock signal CLK is at the L level, and outputs both the P-side signal V_{A} and the N-side signal V_{B} at the H levels by the reset operation. The comparator 21 performs a sampling operation in the period in which the clock signal CLK is at the H level. The comparator 21 can be configured as illustrated in FIG. 3. FIG. 3 is a circuit diagram illustrating the configuration of the comparator 21.

The comparator 21 includes NMOS transistors NM1, NM2, NM3, NM4, NM5, and NM6, PMOS transistors PM1 and PM2, an N-type switch NS1, P-type switches PS1, PS2, PS3, PS4, and PS5, and an inverter INV1.

The NMOS transistor NM1 has a gate electrically connected to the signal input node 21a, a drain electrically connected to a node N1, and a source electrically connected to one end of the N-type switch NS1. The data signal V_{AFEp} is input to the gate of the NMOS transistor NM1.

The NMOS transistor NM2 has a gate electrically connected to the signal input node 21b, a drain electrically connected to a node N2, and a source electrically connected to one end of the N-type switch NS1. The data signal V_{AFEn} is input to the gate of the NMOS transistor NM2.

The NMOS transistor NM3 has a gate electrically connected to the input node 21d, a drain electrically connected to the node N1, and a source electrically connected to one end of the N-type switch NS1. The reference signal V_{REFn} is input to the gate of the NMOS transistor NM3.

The NMOS transistor NM4 has a gate electrically connected to the input node 21c, a drain electrically connected to the node N2, and a source electrically connected to one end of the N-type switch NS1. The reference signal V_{REFp} is input to the gate of the NMOS transistor NM4.

The NMOS transistor NM5 has a gate electrically connected to the output node 21f, one end of the P-type switch PS1, and one end of the P-type switch PS2, a drain electrically connected to the output node 21g, and a source electrically connected to the node N1.

The NMOS transistor NM6 has a gate electrically connected to the output node 21g, the other end of the P-type switch PS1, and one end of the P-type switch PS3, a drain electrically connected to the output node 21f, and a source electrically connected to the node N2.

The N-type switch NS1 has one end electrically connected to the source of each of the NMOS transistors NM1, NM2, NM3, and NM4, the other end electrically connected to a node having a ground potential, and a control terminal electrically connected to the input node 21e. The N-type switch NS1 can be composed of an NMOS transistor. The clock CLK is input to the control terminal of the N-type switch NS1. The N-type switch NS1 is turned on when the clock CLK becomes an active level (for example, H level), and turned off when the clock CLK becomes a non-active level (for example, L level).

The PMOS transistor PM1 has a gate electrically connected to the output node 21f, one end of the P-type switch PS1, and one end of the P-type switch PS2, a drain electrically connected to the output node 21g, and a source electrically connected to a node having a power supply potential.

The PMOS transistor PM2 has a gate electrically connected to the output node 21g, the other end of the P-type switch PS1, and one end of the P-type switch PS3, a drain electrically connected to the output node 21f, and a source electrically connected to a node having a power supply potential.

The P-type switch PS1 has one end electrically connected to the output node 21f, the gate of the NMOS transistor NM5, and the gate of the PMOS transistor PM1, the other end electrically connected to the output node 21g, the gate of the NMOS transistor NM6, and the gate of the PMOS transistor PM2, and a control terminal electrically connected to the input node 21e via the inverter INV1. The P-type switch PS1 can be composed of a PMOS transistor. An inverted clock CLKB is input to the control terminal of the P-type switch PS1. The inverted clock CLKB is generated by logically inverting the clock CLK by the inverter INV1. The P-type switch PS1 is turned on when the inverted clock CLKB becomes an active level (for example, H level), and turned off when the inverted clock CLKB becomes a non-active level (for example, L level).

The P-type switch PS2 has one end electrically connected to the output node 21f, the gate of the NMOS transistor NM5, and the gate of the PMOS transistor PM1, the other end electrically connected to a node having a power supply potential, and a control terminal electrically connected to the input node 21e via the inverter INV1. The P-type switch PS2 can be composed of the PMOS transistor. The inverted clock CLKB is input to the control terminal of the P-type switch PS2. The P-type switch PS2 is turned on when the inverted clock CLKB becomes an active level (for example, H level), and turned off when the inverted clock CLKB becomes a non-active level (for example, L level).

The P-type switch PS3 has one end electrically connected to the output node 21g, the gate of the NMOS transistor NM6, and the gate of the PMOS transistor PM2, the other end electrically connected to a node having a power supply potential, and a control terminal electrically connected to the input node 21e via the inverter INV1. The P-type switch PS3 can be composed of the PMOS transistor. The inverted clock CLKB is input to the control terminal of the P-type switch PS3. The P-type switch PS3 is turned on when the inverted clock CLKB becomes an active level (for example, H level), and turned off when the inverted clock CLKB becomes a non-active level (for example, L level).

The P-type switch PS4 has one end electrically connected to the node N2, the other end electrically connected to a node having a power supply potential, and a control terminal electrically connected to the input node 21e via the inverter INV1. The P-type switch PS4 can be composed of the PMOS transistor. The inverted clock CLKB is input to the control terminal of the P-type switch PS4. The P-type switch PS4 is turned on when the inverted clock CLKB becomes an active level (for example, H level), and turned off when the inverted clock CLKB becomes a non-active level (for example, L level).

The P-type switch PS5 has one end electrically connected to the node N1, the other end electrically connected to a node having a power supply potential, and a control terminal electrically connected to the input node 21e via the inverter INV1. The P-type switch PS5 can be composed of the PMOS transistor. The inverted clock CLKB is input to the control terminal of the P-type switch PS5. The P-type switch PS5 is turned on when the inverted clock CLKB becomes an active level (for example, H level), and turned off when the inverted clock CLKB becomes a non-active level (for example, L level).

Referring back to FIG. 2, the latch circuit 22 is electrically connected between the comparator 21, and the replica logic circuit 25 and the logic circuit 26. The latch circuit 22 is connected in parallel with the offset adjustment circuit 23 and the offset adjustment circuit 24 between the comparator 21, and the replica logic circuit 25 and the logic circuit 26.

For example, the latch circuit 22 may be an S⁻R⁻ latch circuit. The latch circuit 22 includes an input node 22a, an input node 22b, an output node 22c, an output node 22d, a logic gate 22e, and a logic gate 22f.

The input node 22a is a P-side input node, and the P-side line L1 is electrically connected thereto. The input node 22a is electrically connected to the output node 21f of the comparator 21 via the line L1, and receives the P-side signal V_{A} in the comparison result from the comparator 21 via the line L1.

The input node 22b is an N-side input node, and the N-side line L2 is electrically connected thereto. The input node 22b is electrically connected to the output node 21g of the comparator 21 via the line L2, and receives the N-side signal V_{B} in the comparison result from the comparator 21 via the line L2.

The output node 22c is a P-side output node, and the P-side lines L3 and L15 are electrically connected thereto. The output node 22c is electrically connected to the replica logic circuit 25 via the line L3, and is electrically connected to the offset adjustment circuit 23 via the line L15.

The output node 22d is an N-side output node, and the N-side lines L4 and L16 are electrically connected thereto. The output node 22d is electrically connected to the logic circuit 26 via the line L4, and is electrically connected to the offset adjustment circuit 24 logic circuit via the line L16.

The logic gate 22e and the logic gate 22f have an equivalent configuration. In the logic gate 22e and the logic gate 22f, one of two input nodes and an output node of the other logic gate are connected in a cross-coupled manner.

The logic gate 22e includes a NAND gate NA1. The NAND gate NA1 includes a first input node electrically connected to the line L1, a second input node electrically connected to the line L4, and an output node electrically connected to the line L3. The logic gate 22f includes a NAND gate NA2. The NAND gate NA2 includes a first input node electrically connected to the line L2, a second input node electrically connected to the line L3, and an output node electrically connected to the line L4. The output node of the NAND gate NA1 is electrically connected to the second input node of the NAND gate NA2. The output node of the NAND gate NA2 is electrically connected to the second input node of the NAND gate NA1. The first input node of the NAND gate NA1 is electrically connected to the input node 22a, and the first input node of the NAND gate NA2 is electrically connected to the input node 22b. The output node of the NAND gate NA1 is electrically connected to the output node 22c, and the output node of the NAND gate NA2 is electrically connected to the output node 22d.

The offset adjustment circuit 23 is electrically connected between the comparator 21 and the replica logic circuit 25. The offset adjustment circuit 23 is electrically connected to the line L1 (L12), the line L3, and the line L5. The offset adjustment circuit 23 is connected in parallel to the latch circuit 22 between the line L1 and the line L3.

The offset adjustment circuit 23 has a circuit configuration equivalent to the offset adjustment circuit 24. The offset adjustment circuit 23 includes an input node 23a, an input node 23b, an output node 23c, and a logic gate 23d.

The input node 23a is electrically connected to the P-side line L1 (L12). The input node 23a is electrically connected to the output node 21f of the comparator 21 via the line L1 (L12), and receives the P-side signal V_{A} in the comparison result from the comparator 21 via the line L1 (L12).

The input node 23b is electrically connected to the P-side line L3 (L15). The input node 23b is electrically connected to the output node 22c of the latch circuit 22 via the line L3 (L15), and receives a P-side signal V_{AR} from the latch circuit 22 via the line L3 (L15).

The output node 23c is electrically connected to the line L5. The potential of the line L5 is floating in the initial state. The output node 23c supplies a signal V_{AF} corresponding to the signal V_{A} of the line L1 (L12) and the signal V_{AR} of the line L3 (L15) to the line L5.

The logic gate 23d has a configuration equivalent to the logic gate 22e or the logic gate 22f. The logic gate 23d includes a NAND gate NA3. The NAND gate NA3 includes a first input node electrically connected to the line L1, a second input node electrically connected to the line L3 via the line L15, and an output node electrically connected to the line L5. The first input node of the NAND gate NA3 is electrically connected to the input node 23a, the second input node of the NAND gate NA3 is electrically connected to the input node 23b, and the output node of the NAND gate NA3 is electrically connected to the output node 23c.

The offset adjustment circuit 24 is electrically connected between the comparator 21 and the logic circuit 26. The offset adjustment circuit 24 is electrically connected between the line L2 and the line L4. The offset adjustment circuit 24 is connected in parallel to the latch circuit 22 between the line L2 and the line L4.

The offset adjustment circuit 24 has a circuit configuration equivalent to the offset adjustment circuit 23. The offset adjustment circuit 24 includes an input node 24a, an input node 24b, an output node 24c, and a logic gate 24d.

The input node 24a is electrically connected to the N-side line L2. The input node 24a is electrically connected to the output node 21g of the comparator 21 via the line L2, and receives the N-side signal V_{B} in the comparison result from the comparator 21 via the line L2.

The input node 24b is electrically connected to the N-side line L4. The input node 24b is electrically connected to the output node 22c of the latch circuit 22 via the line L4, and receives an N-side signal V_{BR} from the latch circuit 22 via the line L4.

The output node 24c is electrically connected to the line L6. The potential of the line L6 is floating in the initial state. The output node 24c supplies a signal V_{BF} corresponding to the signal V_{B} of the line L2 and the signal V_{BR} of the line L4 to the line L6.

The logic gate 24d has a configuration equivalent to the logic gate 22e or the logic gate 22f. The logic gate 24d includes a NAND gate NA4. The NAND gate NA4 includes a first input node electrically connected to the line L2, a second input node electrically connected to the line L4 via the line L16, and an output node electrically connected to the line L6. The first input node of the NAND gate NA4 is electrically connected to the input node 24a, the second input node of the NAND gate NA4 is electrically connected to the input node 24b, and the output node of the NAND gate NA4 is electrically connected to the output node 24c.

The replica logic circuit 25 is a dummy logic circuit provided in order to achieve a circuit balance in relation to the logic circuit 26. In the replica logic circuit 25, the line L3 is electrically connected to the input terminal.

The logic circuit 26 transfers the result sampled by the edge sampler 2e to the CDR 202. In the logic circuit 26, the line L4 is electrically connected to the input terminal, a clock signal CK is supplied to the clock input terminal, and the CDR 202 is electrically connected to the output terminal. The logic circuit 26 holds the signal V_{BR} of the line L4 in synchronization with the clock signal CK (for example, in synchronization with the rising edge of the clock signal CK), and outputs the held signal from an output terminal Q to the CDR 202. The logic circuit 26 may be a buffer circuit that does not require the clock signal CK.

In the edge sampler 2e illustrated in FIG. 2, as indicated by a dotted line, a parasitic coupling capacitance C13 is formed between the line L1 and the line L3, and a parasitic coupling capacitance C15 is formed between the line L1 and the line L5, a parasitic coupling capacitance C24 is formed between the line L2 and the line L4, and a parasitic coupling capacitance C26 is formed between the line L2 and the line L6. When the layout distance of the line L1 and the line L3 and the layout distance of the line L1 and the line L5 are substantially the same, the value of the coupling capacitance satisfies the relationship of the following Expression 1.

C13≈C15 Expression 1

When the layout distance of the line L2 and the line L4 and the layout distance of the line L2 and the line L6 are substantially the same, the value of the coupling capacitance satisfies the relationship of the following Expression 2.

C24≈C26 Expression 2

When the layout of the offset adjustment circuit 23 and the layout of the offset adjustment circuit 24 are symmetric with respect to the latch circuit 22, it can be considered that the layout distance of the line L1 and the line L3, the layout distance of the line L1 and the line L5, the layout distance of the line L2 and the line L4, and the layout distance of the line L2 and the line L6 are substantially the same. In this case, the following Expression 3 is established. Here, C is a constant.

C13≈C15≈C24≈C26=C Expression 3

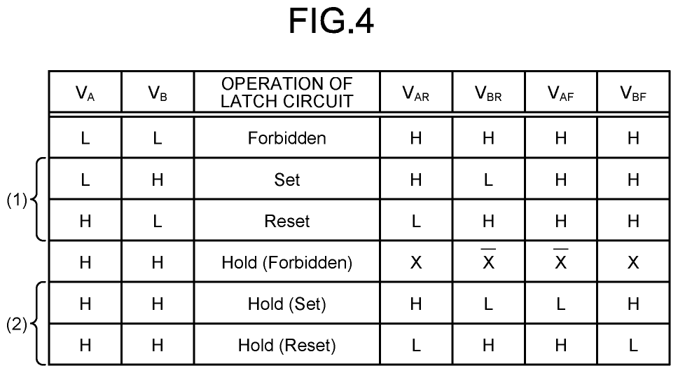

In this configuration, the latch circuit 22, the offset adjustment circuit 23, and the offset adjustment circuit 24 can operate as illustrated in FIG. 4. FIG. 4 is a diagram illustrating operations of the latch circuit 22 and the offset adjustment circuits 23 and 24.

As mentioned before, the comparator 21 performs the sampling operation in the period in which the clock CLK is at the H level, and performs the reset operation in the period in which the clock CLK is at the L level. In the period during which the comparator 21 performs the sampling operation (sampling period), the sampling result (V_{A}, V_{B}) of the comparator 21 may be any of the two levels shown in (1). In the period during which the comparator 21 performs the reset operation (reset period), the sampling result (V_{A}, V_{B}) of the comparator 21 is the level shown in (2). The offset component from the latch circuit 22 side affects the hysteresis of the comparator 21 at the level of the output node of the comparator 21 at the timing of transition from the reset period to the sampling period. For this reason, during the reset period, it is desirable that the offset components appearing at the output nodes of the comparator 21 are equal between the differential pairs. Note that, in the latch circuit 22, it is designed so that the operation of latching the two inputs (V_{A}, V_{B}) at the L levels is a forbidden operation (Forbidden), and the sampling result (V_{A}, V_{B})=(L level, L level) is not output from the comparator 21. If the latch circuit 22 latches (V_{A}, V_{B})=(L level, L level) during the sampling period, the value held in the latch circuit 22 by a hold operation (Hold (Forbidden)) in the subsequent reset period becomes an indefinite value (X or X⁻).

For example, in “Hold (Set)” in the reset period after the sampling period, the latch circuit 22 performs a set operation (Set) in the immediately preceding sampling period and performs a hold operation (Hold) in the current reset period.

In the immediately preceding sampling period, the comparator 21 performs a sampling operation, outputs the signal V_{A}=L level to the line L1, and outputs the signal V_{B}=H level to the line L2. In response, the latch circuit 22 performs a set operation (Set) of setting a value held for the P side to the H level, outputs the signal V_{AR}=H level to the line L3, and outputs the signal V_{BR}=L level to the line L4. Further, the offset adjustment circuit 23 calculates a negative logical product of the signal V_{A}=L level and the signal V_{AR}=H level, and outputs the signal V_{AF}=H level to the line L5. The offset adjustment circuit 24 calculates a negative logical product of the signal V_{B}=H level and the signal V_{BR}=L level, and outputs the signal V_{BF}=H level to the line L6.

In the current reset period, the comparator 21 performs a reset operation of setting an output value to the H level, outputs the signal V_{A}=H level to the line L1, and outputs the signal V_{B}=H level to the line L2. In response, the latch circuit 22 performs a hold operation “Hold (Set)” of holding the level latched in the immediately preceding set operation, outputs the signal V_{AR}=H level to the line L3, and outputs the signal V_{BR}=L level to line L4. Further, the offset adjustment circuit 23 calculates a negative logical product of the signal V_{A}=H level and the signal V_{AR}=H level, and outputs the signal V_{AF}=L level to the line L5. The offset adjustment circuit 24 calculates a negative logical product of the signal V_{B}=H level and the signal V_{BR}=L level, and outputs the signal V_{BF}=H level to the line L6.

At this time, both ends of the coupling capacitance C13 (between L1 and L3) illustrated in FIG. 2 are at the H levels, and one end of the coupling capacitance C15 (between L1 and L5) is at the H level and the other end thereof is at the L level. Thereby, there is substantially no charge transfer between the line L3 and the line L1 via the coupling capacitance C13, but charge transfer between the line L5 and the line L1 via the coupling capacitance C15 can occur according to the difference between the H level and the L level. Thereby, an offset component corresponding to the difference between the H level and the L level appears on the line L1. That is, assuming that the amount of charge transfer due to the difference between the H level and the L level is ΔQ_{HL1} and a predetermined coefficient is k, an offset comp component ΔV_{OF1} appearing at the output node 21f of the comparator 21 is represented by the following Expression 4.

ΔV_{OF1}=k×ΔQ_{HL1}/C Expression 4

Further, both ends of the coupling capacitance C26 (between L2 and L6) are at the H levels, and one end of the coupling capacitance C24 (between L2 and L4) is at the H level and the other end thereof is at the L level. Thereby, there is substantially no charge transfer between the line L6 and the line L2 via the coupling capacitance C26, but charge transfer between the line L4 and the line L2 via the coupling capacitance C24 can occur according to the difference between the H level and the L level. Thereby, an offset component corresponding to the difference between the H level and the L level appears on the line L2. That is, assuming that the amount of charge transfer due to the difference between the H level and the L level is ΔQ_{HL2} and a predetermined coefficient is k, an offset component ΔV_{OF2} appearing at the output node 21g of the comparator 21 is represented by the following Expression 5.

ΔV_{OF2}=k×ΔQ_{HL2}/C Expression 5

That is, the offset components appearing at the output nodes 21f and 21g of the comparator 21 are all offset components corresponding to the difference between the H level and the L level, and if the amount of charge transfer is equal (ΔQ_{HL1}≈ΔQ_{HL2}), as shown in Expressions 4 and 5, the offset components can be equal to each other.

Alternatively, in “Hold (Reset)” in the reset period after the sampling period illustrated in FIG. 4, the latch circuit 22 performs a reset operation (Reset) in the immediately preceding sampling period and performs a hold operation (Hold) in the current reset period.

In the immediately preceding sampling period, the comparator 21 performs a sampling operation, outputs the signal V_{A}=H level to the line L1, and outputs the signal V_{B}=L level to the line L2. In response, the latch circuit 22 performs a reset operation (Reset) of setting a value held for the N side to the H level, outputs the signal V_{AR}=L level to the line L3, and outputs the signal V_{BR}=H level to the line L4. Further, the offset adjustment circuit 23 calculates a negative logical product of the signal V_{A}=H level and the signal V_{AR}=L level, and outputs the signal V_{AF}=H level to the line L5. The offset adjustment circuit 24 calculates a negative logical product of the signal V_{B}=L level and the signal V_{BR}=H level, and outputs the signal V_{BF}=H level to the line L6.

In the current reset period, the comparator 21 performs a reset operation, outputs the signal V_{A}=H level to the line L1, and outputs the signal V_{B}=H level to the line L2. In response, the latch circuit 22 performs a hold operation “Hold (Reset)” of holding the level latched in the immediately preceding reset operation, outputs the signal V_{AR}=L level to the line L3, and outputs the signal V_{BR}=H level to line L4. Further, the offset adjustment circuit 23 calculates a negative logical product of the signal V_{A}=H level and the signal V_{AR}=L level, and outputs the signal V_{AF}=H level to the line L5. The offset adjustment circuit 24 calculates a negative logical product of the signal V_{B}=H level and the signal V_{BR}=H level, and outputs the signal V_{BF}=L level to the line L6.

At this time, both ends of the coupling capacitance C15 (between L1 and L5) illustrated in FIG. 2 are at the H levels, and one end of the coupling capacitance C13 (between L1 and L3) is the H level and the other end thereof is the L level. Thereby, there is substantially no charge transfer between the line L5 and the line L1 via the coupling capacitance C15, but charge transfer between the line L3 and the line L1 via the coupling capacitance C13 can occur according to the difference between the H level and the L level. Thereby, an offset component corresponding to the difference between the H level and the L level appears on the line L1. That is, assuming that the amount of charge transfer due to the difference between the H level and the L level is ΔQ_{HL1}′ and a predetermined coefficient is k, an offset component ΔV_{OF1}′ appearing at the output node 21f of the comparator 21 is represented by the following Expression 6.

ΔV_{OF1}′=k×ΔQ_{HL1}′/C Expression 6

Further, both ends of the coupling capacitance C24 (between L2 and L4) are at the H levels, and one end of the coupling capacitance C26 (between L2 and L6) is at the H level and the other end thereof is at the L level. Thereby, there is substantially no charge transfer between the line L4 and the line L2 via the coupling capacitance C24, but charge transfer between the line L6 and the line L2 via the coupling capacitance C26 can occur according to the difference between the H level and the L level. Thereby, an offset component corresponding to the difference between the H level and the L level appears on the line L2. That is, assuming that the amount of charge transfer due to the difference between the H level and the L level is ΔQ_{HL2}′ and a predetermined coefficient is k, an offset component ΔV_{OF2}′ appearing at the output node 21g of the comparator 21 is represented by the following Expression 7.

ΔV_{OF2}′=k×ΔQ_{HL2}′/C Expression 7

That is, the offset components appearing at the output nodes 21f and 21g of the comparator 21 are all offset components corresponding to the difference between the H level and the L level, and if the amount of charge transfer is equal (ΔQ_{HL1}′≈ΔQ_{HL2}′), as shown in Expressions 6 and 7, the offset components can be equal to each other.

In this way, when the offset components appearing at the output nodes 21f and 21g of the comparator 21 are equal to each other, the P-side signal and the N-side signal are both shifted by equal offset components in the comparator 21, so that the offset components can be canceled by the comparator 21. Thereby, since the deviation of the threshold value of the sampling of the comparator (that is, comparison operation) from an appropriate level (≈potential of the reference signal) can be suppressed, the indefinite interval of the comparison operation of the comparator can be reduced. That is, the hysteresis of the comparator 21 can be suppressed.

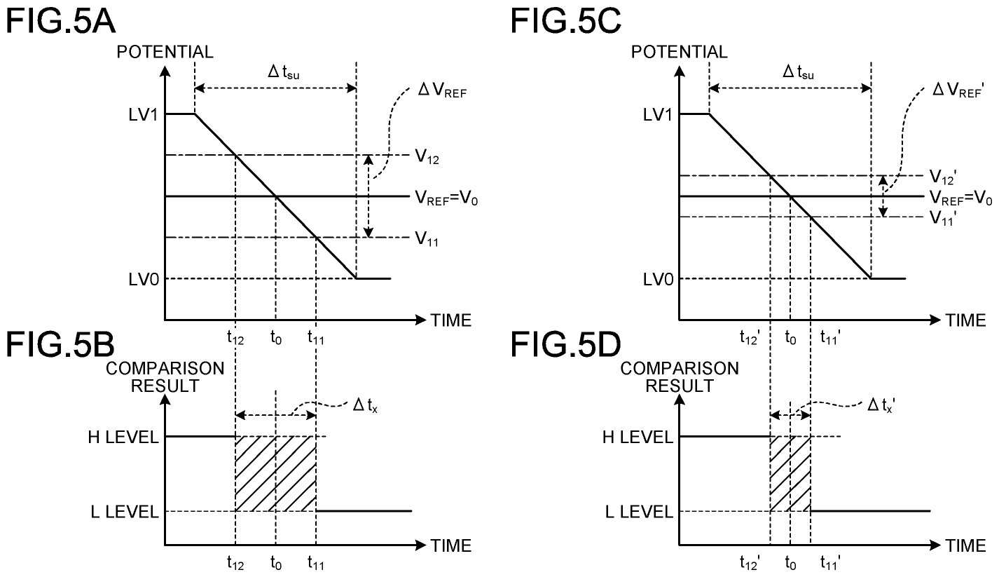

For example, as illustrated in FIG. 5A, when unbalanced offset components are mixed between differential pairs in the differential output node of the comparator, and the offset components are difficult to cancel by the comparator 21, if the threshold value of the sampling of the comparator fluctuates in V₁₁ to V₁₂ of a wide voltage range including the reference signal V_{REF}=V₀, as illustrated by the diagonal hatching in FIG. 5B, an indefinite interval occurs in t₁₂ to t₁₁ of a wide time range including timing t₀ at which the data signal V_{AFE} crosses V_{REF}=V₀ vertically. That is, a voltage fluctuation width ΔV_{REF} of the threshold value V_{REF} is wide, and correspondingly, a ratio Δtₓ/Δt_{SU} of a time width Δt_{X} of the indefinite interval to a transition time Δt_{SU} of the data signal V_{AFE} is relatively large.

On the other hand, as illustrated in FIG. 5C, when the P-side signal and the N-side signal are both shifted by the equal offset components in the comparator 21, and the offset components can be canceled by the comparator 21, the threshold value of the sampling of the comparator fluctuates in V₁₁′ to V₁₂′ of a narrower voltage range. Accordingly, as illustrated by the diagonal hatching in FIG. 5D, an indefinite interval occurs in t₁₂′ to t₁₁′ of a narrower time range. That is, a voltage fluctuation width ΔV_{REF}′ of the threshold value V_{REF} is narrower than ΔV_{REF}, and correspondingly, a ratio Δtₓ′/Δt_{SU} of a time width Δt_{X} of the indefinite interval to the transition time Δt_{SU} of the data signal V_{AFE} is smaller than Δt_{X}/Δt_{SU}. Thereby, the sampling of the edge sampler 2e can be performed at the level of the data signal V_{AFE} closer to the threshold value V_{REF},and the temporal accuracy of the sampling result of the edge sampler 2e can be improved.

As described above, in the embodiment, in the edge sampler 2e, the offset adjustment circuits 23 and 24 are respectively added for the differential pairs between the input nodes 22a and 22b and the output nodes 22c and 22d of the latch circuit 22. Thereby, the offset components appearing at the input nodes 22a and 22b can be equalized between the differential pairs, so that the pair of differential signals can be optimized and the hysteresis of the comparator 21 can be relaxed.

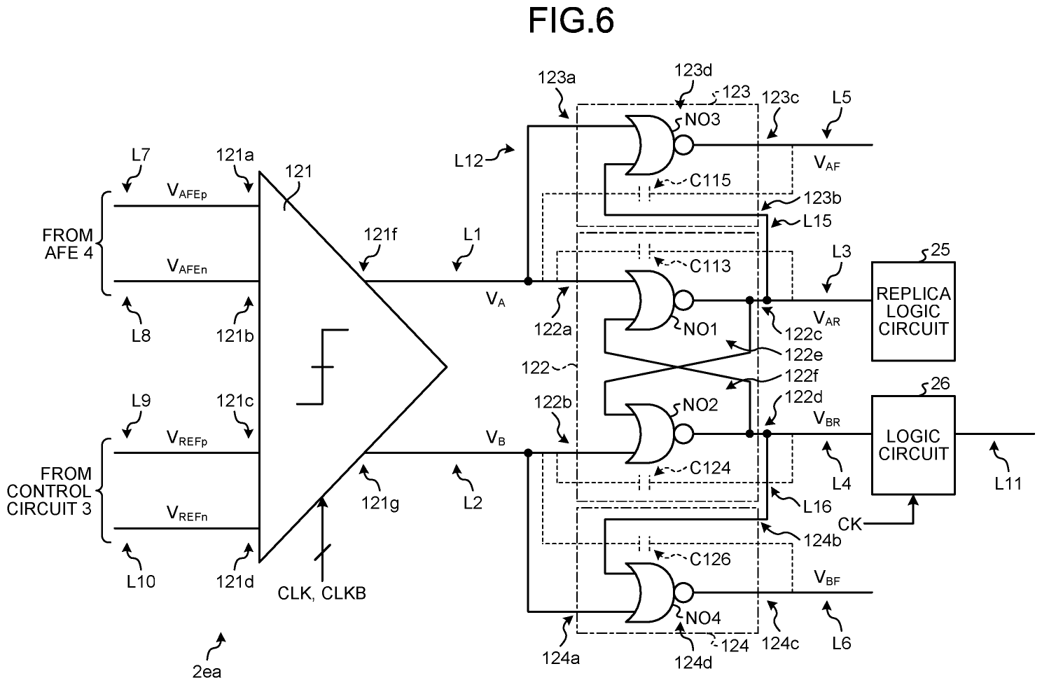

It should be noted that, as illustrated in FIG. 6, a latch circuit 122 may be an SR latch circuit including a NOR gate, offset adjustment circuits 123 and 124 may be configured accordingly, and a comparator 121 may be an L reset comparator. FIG. 6 is a circuit diagram illustrating a configuration of an edge sampler 2ea in a first modification example of the embodiment.

The edge sampler 2ea of the present first modification example includes the comparator 121, the latch circuit 122, the offset adjustment circuit 123, and the offset adjustment circuit 124 instead of the comparator 21, the latch circuit 22, the offset adjustment circuit 23, and the offset adjustment circuit 24 of the embodiment (see FIG. 2).

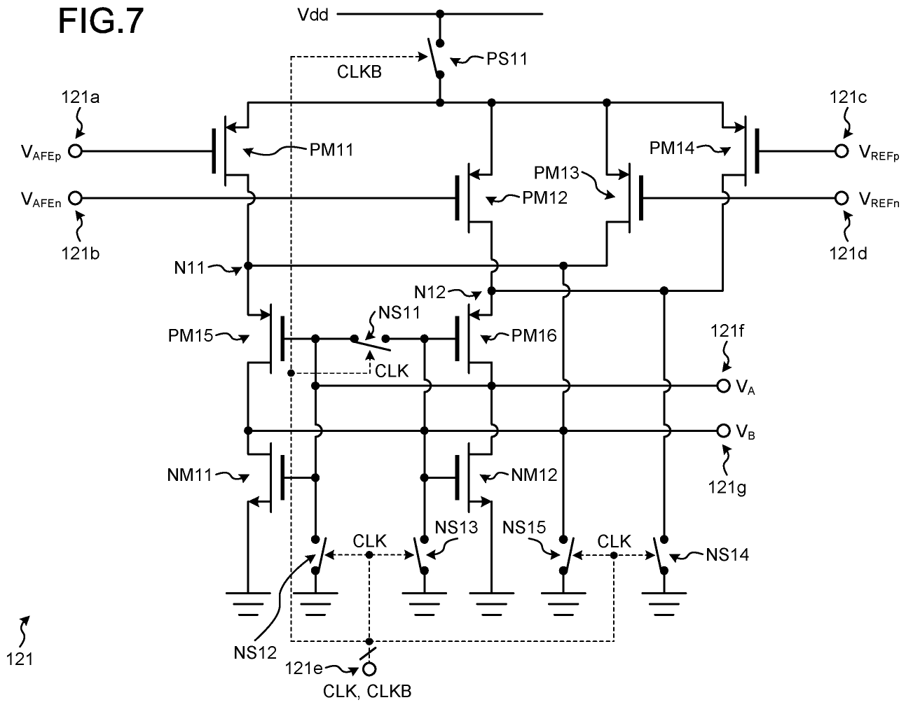

The comparator 121 includes an input node 121a, an input node 121b, an input node 121c, an input node 121d, an input node 121e, an output node 121f, and an output node 121g. The comparator 121 is an L reset (low reset) comparator. The comparator 121 performs a reset operation in the period in which the clock signal CLK is at the L level, and outputs both the P-side signal V_{A} and the N-side signal V_{B} at the L levels by the reset operation. The comparator 121 can be configured as illustrated in FIG. 7. FIG. 7 is a circuit diagram illustrating the configuration of the comparator 121.

The comparator 121 includes PMOS transistors PM11, PM12, PM13, PM14, PM15, and PM16, NMOS transistors NM11 and NM12, a P-type switch PS11, and N-type switches NS11, NS12, NS13, NS14, and NS15. Each element described above is obtained by inverting the polarity with respect to each element illustrated in FIG. 3. That is, the description of each element illustrated in FIG. 7 can be similarly applied by replacing the NMOS transistors NM1 to NM6 and the N-type switch NS1 (see FIG. 3) with the PMOS transistors PM11 to PM16 and the P-type switch PS11, and replacing the PMOS transistors PM1 and PM2 and the P-type switches PS1 to PS5 with the NMOS transistors NM11 and NM12 and the N-type switches NS11 to NS15 in the description of each element illustrated in FIG. 3.

Referring back to FIG. 6, for example, the latch circuit 122 is an SR latch circuit, and includes an input node 122a, an input node 122b, an output node 122c, an output node 122d, a logic gate 122e, and a logic gate 122f. The logic gate 122e includes a NOR gate N01. The logic gate 122f includes a NOR gate NO2.

The offset adjustment circuit 123 has a circuit configuration equivalent to the offset adjustment circuit 124. The offset adjustment circuit 123 includes an input node 123a, an input node 123b, an output node 123c, and a logic gate 123d. The logic gate 123d includes a NOR gate NO3.

The offset adjustment circuit 124 has a circuit configuration equivalent to the offset adjustment circuit 123. The offset adjustment circuit 124 includes an input node 124a, an input node 124b, an output node 124c, and a logic gate 124d. The logic gate 124d includes a NOR gate NO4.

In the edge sampler 2ea illustrated in FIG. 6, parasitic coupling capacitances C113 and C115 are formed between the line L1 and each of the lines L3 and L5, respectively, and parasitic coupling capacitances C124 and C126 are formed between the line L2 and each of the lines L4 and L6, respectively. This configuration is the same as that of the edge sampler 2e illustrated in FIG. 2.

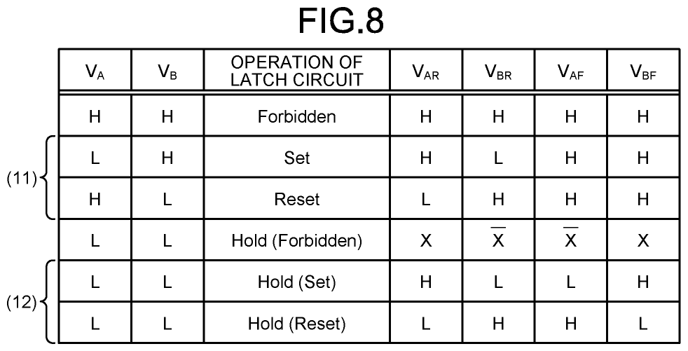

Further, for the operations of the latch circuit 122 and the offset adjustment circuits 123 and 124, as illustrated in FIG. 8, the polarities of the input signals (V_{A}, V_{B}) other than during the set operation and the reset operation by the latch circuit 122 are inverted with respect to the operations of the latch circuit 22 and the offset adjustment circuits 23 and 24 (see FIG. 4), but the polarities of the input signals (V_{A}, V_{B}) other than during the set operation and the reset operation and the polarities of the output signals (V_{AR}, V_{BR}, V_{AF}, V_{BF}) are the same as the operations of the latch circuit 22 and the offset adjustment circuits 23 and 24.

The operation results of the latch circuit 122 and the offset adjustment circuits 123 and 124 in the sampling period of the comparator 121 can be the levels shown in (11), and the operation results of the latch circuit 122 and the offset adjustment circuits 123 and 124 in the reset period of the comparator 121 can be the levels shown in (12). The offset component from the latch circuit 122 side affects the hysteresis of the comparator 121 at the level of the output node of the comparator 121 at the timing of transition from the reset period to the sampling period. For this reason, during the reset period, it is desirable that the offset components appearing at the output nodes of the comparator 121 are equal between the differential pairs. Note that, in the latch circuit 122, it is designed so that the operation of latching the two inputs (V_{A}, V_{B}) at the H levels is a forbidden operation (Forbidden), and the sampling result (V_{A}, V_{B})=(H level, H level) is not output from the comparator 121. If the latch circuit 122 latches (V_{A}, V_{B})=(H level, H level) during the sampling period, the value held in the latch circuit 122 by a hold operation (Hold (Forbidden)) in the subsequent reset period becomes an indefinite value (X or X⁻).

For example, in “Hold (Set)” in the reset period after the sampling period, the latch circuit 122 performs a set operation (Set) in the immediately preceding sampling period and performs a hold operation (Hold) in the current reset period.

At this time, both ends of the coupling capacitance C115 (between L1 and L5) illustrated in FIG. 6 are at the L levels, and one end of the coupling capacitance C113 (between L1 and L3) is at the L level and the other end thereof is at the H level. Thereby, there is substantially no charge transfer between the line L5 and the line L1 via the coupling capacitance C115, but charge transfer between the line L3 and the line L1 via the coupling capacitance C113 can occur according to the difference between the L level and the H level. Thereby, an offset component corresponding to the difference between the L level and the H level appears on the line L1. That is, assuming that the amount of charge transfer due to the difference between the L level and the H level is ΔQ_{LH1} and a predetermined coefficient is k, an offset component ΔV_{OF1} appearing at the output node 121f of the comparator 121 is represented by the following Expression 8.

ΔV_{OF1}=k×ΔQ_{LH1}/C Expression 8

Further, both ends of the coupling capacitance C124 (between L2 and L4) are at the L levels, and one end of the coupling capacitance C126 (between L2 and L6) is at the L level and the other end thereof is at the H level. Thereby, there is substantially no charge transfer between the line L4 and the line L2 via the coupling capacitance C124, but charge transfer between the line L6 and the line L2 via the coupling capacitance C126 can occur according to the difference between the L level and the H level. Thereby, an offset component corresponding to the difference between the L level and the H level appears on the line L2. That is, assuming that the amount of charge transfer due to the difference between the L level and the H level is ΔQ_{LH2} and a predetermined coefficient is k, an offset component ΔV_{OF2} appearing at the output node 121g of the comparator 121 is represented by the following Expression 9.

ΔV_{OF2}=k×ΔQ_{LH2}/C Expression 9

That is, the offset components appearing at the output nodes 121f and 121g of the comparator 121 are all offset components corresponding to the difference between the L level and the H level, and if the amount of charge transfer is equal (ΔQ_{LH1}≈ΔQ_{LH2}), as shown in Expressions 8 and 9, the offset components can be equal to each other.

In this way, when the offset components appearing at the output nodes 121f and 121g of the comparator 121 are equal to each other, the P-side signal and the N-side signal are both shifted by equal offset components in the comparator 121, so that the offset components can be canceled by the comparator 121. Thereby, since the deviation of the threshold value of the sampling of the comparator (that is, comparison operation) from an appropriate level (≈potential of the reference signal) can be suppressed, the indefinite interval of the comparison operation of the comparator can be reduced. That is, the hysteresis of the comparator 121 can be suppressed.

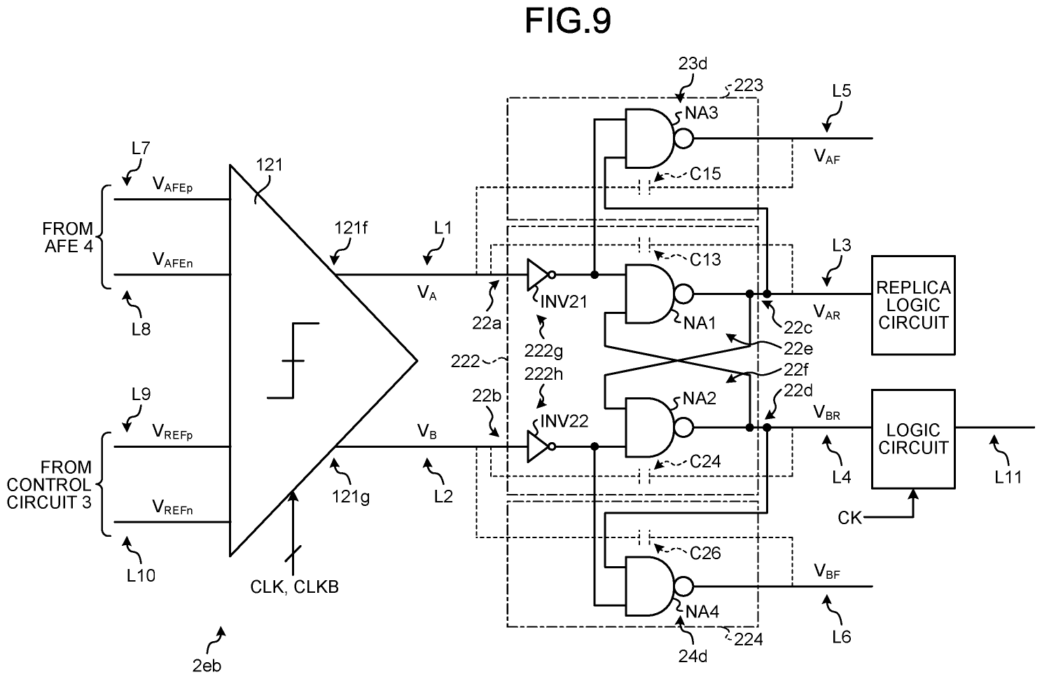

Alternatively, as illustrated in FIG. 9, a latch circuit 222 may be an SR latch circuit including an inverter and a NAND gate, offset adjustment circuits 223 and 224 may be configured accordingly, and a comparator 121 may be an L reset comparator. FIG. 9 is a circuit diagram illustrating a configuration of an edge sampler 2eb in a second modification example of the embodiment.

The edge sampler 2eb of the present second modification example includes the comparator 121, the latch circuit 222, and the offset adjustment circuits 223 and 224 instead of the comparator 21, the latch circuit 22, and the offset adjustment circuits 23 and 24 of the embodiment (see FIG. 2).

The comparator 121 is the same as the comparator 121 of the first modification example illustrated in FIG. 6.

The latch circuit 222 is an SR latch circuit, and logic gates 222g and 222h are added with respect to the latch circuit 22 of the embodiment (see FIG. 2). The logic gate 222g includes an inverter INV21. The logic gate 222h includes an inverter INV22.

The inverter INV21 is electrically connected between the line L1 and the NAND gate NA1. The inverter INV21 has an input node electrically connected to the input node 22a, and an output node electrically connected to the first input node of the NAND gate NA1.

The inverter INV22 is electrically connected between the line L2 and the NAND gate NA2. The inverter INV22 has an input node electrically connected to the input node 22b, and an output node electrically connected to the first input node of the NAND gate NA2.

The offset adjustment circuit 223 is electrically connected to a node between the logic gate 222g and the logic gate 22e in the latch circuit 222, the line L3, and the line L5. The logic gate 23d in the offset adjustment circuit 223 has a first input node electrically connected to the node between the logic gate 222g and the logic gate 22e.

The offset adjustment circuit 224 is electrically connected to a node between the logic gate 222h and the logic gate 22f in the latch circuit 222, the line L4, and the line L6. The logic gate 24d in the offset adjustment circuit 224 has a first input node electrically connected to the node between the logic gate 222h and the logic gate 22f.

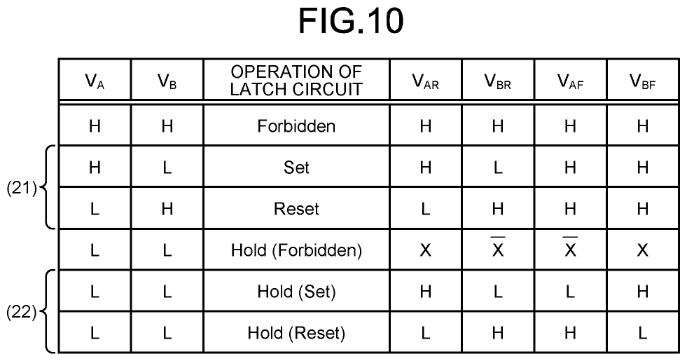

Further, for the operations of the latch circuit 222 and the offset adjustment circuits 223 and 224, as illustrated in FIG. 10, the polarities of the input signals (V_{A}, V_{B}) are inverted with respect to the operations of the latch circuit 22 and the offset adjustment circuits 23 and (see FIG. 4), but the polarities of the output signals (V_{AR}, V_{BR}, V_{AF}, V_{BF}) are the same as the operations of the latch circuit 22 and the offset adjustment circuits 23 and 24.

The operation results of the latch circuit 222 and the offset adjustment circuits 223 and 224 in the sampling period of the comparator 121 can be the levels shown in (21), and the operation results of the latch circuit 222 and the offset adjustment circuits 223 and 224 in the reset period of the comparator 121 can be the levels shown in (22). The offset component from the latch circuit 222 side affects the hysteresis of the comparator 121 at the level of the output node of the comparator 121 at the timing of transition from the reset period to the sampling period. For this reason, during the reset period, it is desirable that the offset components appearing at the output nodes of the comparator 121 are equal between the differential pairs. Note that, in the latch circuit 222, it is designed so that the operation of latching the two inputs (V_{A}, V_{B}) at the H levels is a forbidden operation (Forbidden), and the sampling result (V_{A}, V_{B})=(H level, H level) is not output from the comparator 121. If the latch circuit 222 latches (V_{A}, V_{B})=(H level, H level) during the sampling period, the value held in the latch circuit 222 by a hold operation (Hold (Forbidden)) in the subsequent reset period becomes an indefinite value (X or X⁻).

For example, in “Hold (Set)” in the reset period after the sampling period, the latch circuit 222 performs a set operation (Set) in the immediately preceding sampling period and performs a hold operation (Hold) in the current reset period.

At this time, both ends of a coupling capacitance C15 (between L1 and L5) illustrated in FIG. 9 are at the L levels, and one end of a coupling capacitance C13 (between L1 and L3) is at the L level and the other end thereof is at the H level. Thereby, there is substantially no charge transfer between the line L5 and the line L1 via the coupling capacitance C15, but charge transfer between the line L3 and the line L1 via the coupling capacitance C13 can occur according to the difference between the L level and the H level. Thereby, an offset component corresponding to the difference between the L level and the H level appears on the line L1. That is, assuming that the amount of charge transfer due to the difference between the L level and the H level is ΔQ_{LH1} and a predetermined coefficient is k, an offset component ΔV_{OF1} appearing at the output node 121f of the comparator 121 is represented by Expression 8.

Further, both ends of a coupling capacitance C24 (between L2 and L4) are at the L levels, and one end of the coupling capacitance C26 (between L2 and L6) is at the L level and the other end thereof is at the H level. Thereby, there is substantially no charge transfer between the line L4 and the line L2 via the coupling capacitance C24, but charge transfer between the line L6 and the line L2 via the coupling capacitance C26 can occur according to the difference between the L level and the H level. Thereby, an offset component corresponding to the difference between the L level and the H level appears on the line L2. That is, assuming that the amount of charge transfer due to the difference between the L level and the H level is ΔQ_{LH2} and a predetermined coefficient is k, an offset component ΔV_{OF2} appearing at the output node 121g of the comparator 121 is represented by Expression 9.

In this way, the offset components appearing at the output nodes 121f and 121g of the comparator 121 are all offset components corresponding to the difference between the L level and the H level, and if the amount of charge transfer is equal (ΔQ_{LH1}≈ΔQ_{LH2}), as shown in Expressions 8 and 9, the offset components can be equal to each other.

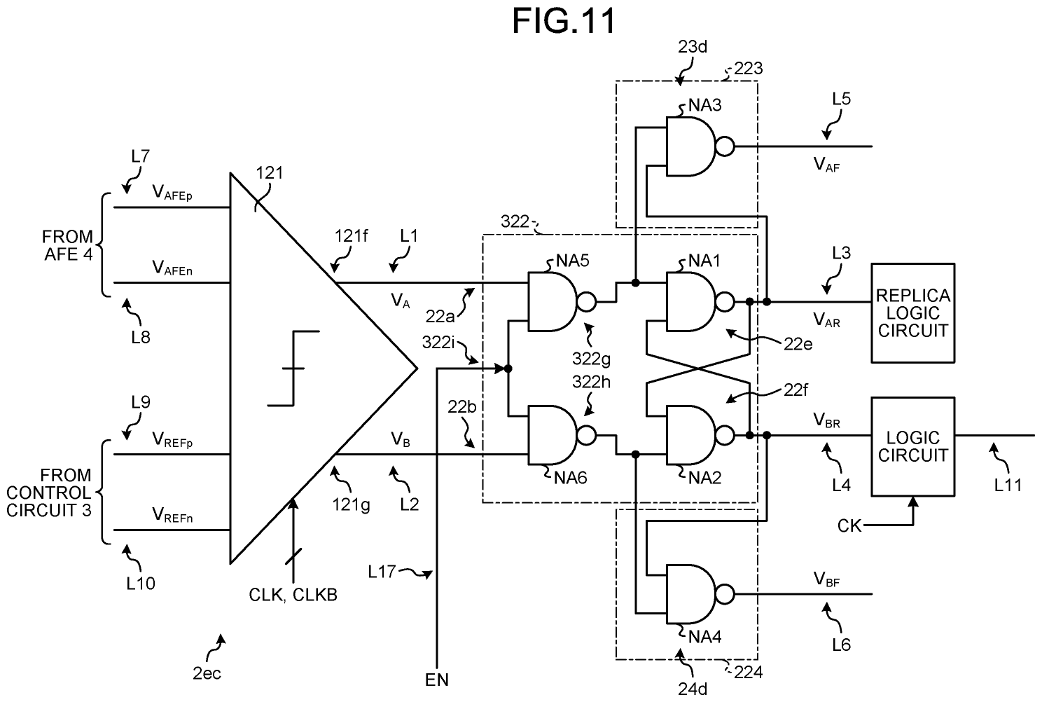

Alternatively, as illustrated in FIG. 11, a latch circuit 322 may be a gated SR latch circuit including a NAND gate. FIG. 11 is a circuit diagram illustrating a configuration of an edge sampler 2ec in a third modification example of the embodiment.

The edge sampler 2ec of the present third modification example includes the latch circuit 322 instead of the latch circuit 222 of the second modification example (see FIG. 9), and further includes a line L17. The line L17 is electrically connected between the control circuit 3 (see FIG. 1) and the latch circuit 322.

The latch circuit 322 includes logic gates 322g and 322h instead of the logic gates 222g and 222h of the second modification example (see FIG. 9), and further includes an input node 322i. The logic gate 222g includes a NAND gate NAS. The logic gate 222h includes a NAND gate NA6. The input node 322i is electrically connected to the control circuit 3 via the line L17. The input node 322i receives an enable signal EN from the control circuit 3 via the line L17.

The NAND gate NA5 is electrically connected between the lines L1 and L17 and the NAND gate NA1. The NAND gate NA5 has a first input node electrically connected to the input node 22a, a second input node electrically connected to the input node 322i, and an output node electrically connected to the first input node of the NAND gate NA1.

The NAND gate NA6 is electrically connected between the lines L2 and L17 and the NAND gate NA2. The NAND gate NA6 has a first input node electrically connected to the input node 22b, a second input node electrically connected to the input node 322i, and an output node electrically connected to the first input node of the NAND gate NA2.

Further, when the enable signal EN received from the control circuit 3 is at a non-active level (for example, L level), the operations of the latch circuit 322 and the offset adjustment circuits 223 and 224 each become a hold operation of holding a state, and when the enable signal EN is at an active level (for example, H level), the operations of the latch circuit 322 and the offset adjustment circuits 223 and 224 are the same as the operations of the second modification example illustrated in FIG. 10.

In this way, even with the configuration illustrated in FIG. 11, the offset components appearing at the output nodes 121f and 121g of the comparator 121 are all offset components corresponding to the difference between the L level and the H level, and as shown in Expressions 8 and 9, the offset components can be equal to each other.

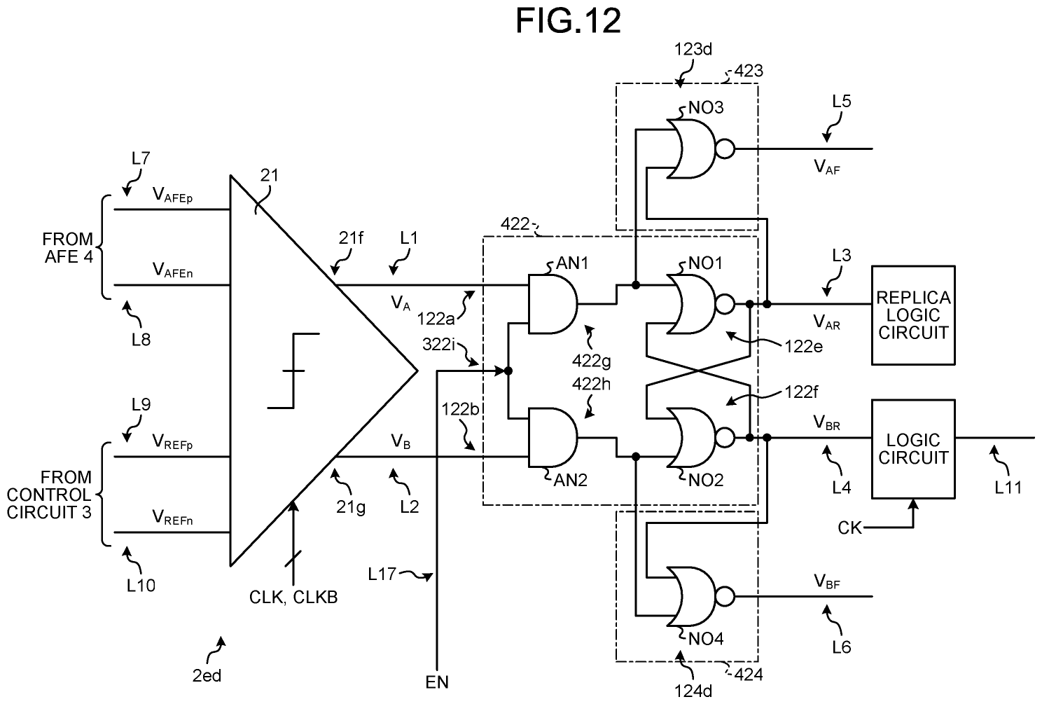

Alternatively, as illustrated in FIG. 12, a latch circuit 422 may be a gated SR latch circuit including an AND gate and a NOR gate. FIG. 12 is a circuit diagram illustrating a configuration of an edge sampler 2ed in a fourth modification example of the embodiment.

The edge sampler 2ed includes a comparator 21, the latch circuit 422, an offset adjustment circuit 423, and an offset adjustment circuit 424 instead of the comparator 121, the latch circuit 122, the offset adjustment circuit 123, and the offset adjustment circuit 124 of the first modification example (see FIG. 6), and further includes a line L17. The line L17 is electrically connected between the control circuit 3 (see FIG. 1) and the latch circuit 422.

The comparator 21 is the same as the comparator 21 of the embodiment illustrated in FIG. 2, and may be an H reset comparator.

The latch circuit 422 further includes a logic gate 422g, a logic gate 422h, and an input node 322i. The logic gate 422g includes an AND gate AN1. The logic gate 422h includes an AND gate AN2. The input node 322i is electrically connected to the control circuit 3 via the line L17. The input node 322i receives an enable signal EN from the control circuit 3 via the line L17.

The AND gate AN1 is electrically connected between the lines L1 and L17 and the NOR gate NO1. The AND gate AN1 has a first input node electrically connected to the input node 122a, a second input node electrically connected to the input node 322i, and an output node electrically connected to the first input node of the NOR gate NO1.

The AND gate AN2 is electrically connected between the lines L2 and L17 and the NOR gate NO2. The AND gate AN2 has a first input node electrically connected to the input node 122b, a second input node electrically connected to the input node 322i, and an output node electrically connected to the first input node of the NOR gate NO2.

Further, when the enable signal EN received from the control circuit 3 is at a non-active level (for example, L level), the operations of the latch circuit 422 and the offset adjustment circuits 423 and 424 each become a hold operation of holding a state, and when the enable signal EN is at an active level (for example, H level), the operations of the latch circuit 422 and the offset adjustment circuits 423 and 424 are the same as the operations of the first modification example illustrated in FIG. 8.

In this way, even with the configuration illustrated in FIG. 12, the offset components appearing at the output nodes 21f and 21g of the comparator 21 are all offset components corresponding to the difference between the L level and the H level, and as shown in Expressions 8 and 9, the offset components can be equal to each other.

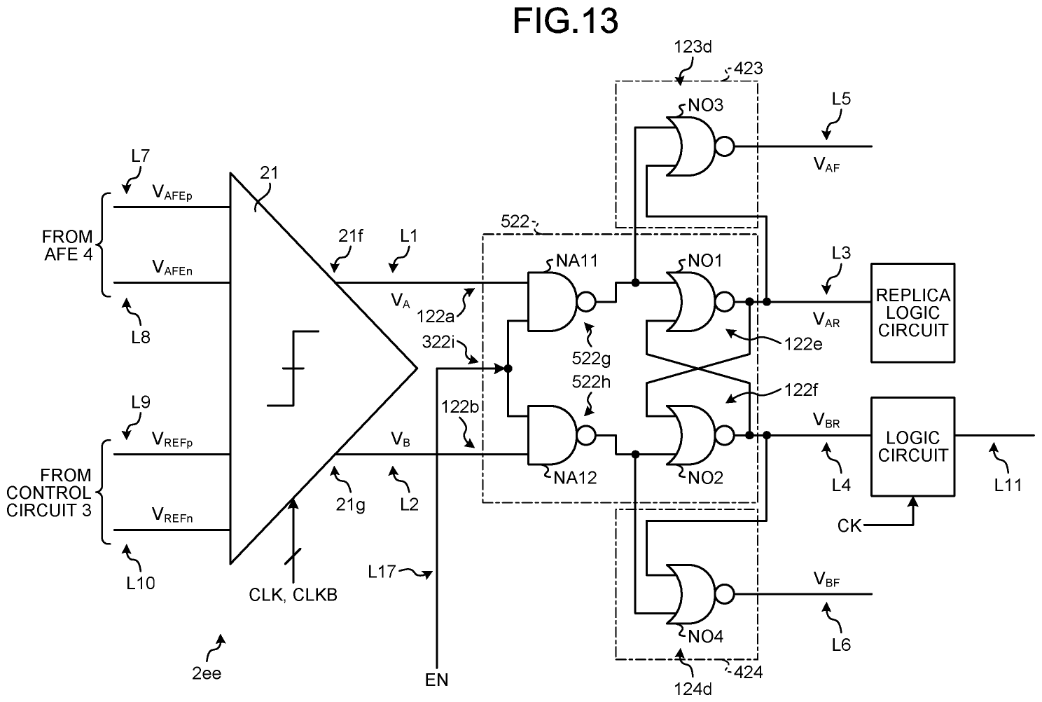

Alternatively, as illustrated in FIG. 13, a latch circuit 522 may be a gated S⁻R⁻ latch circuit including a NAND gate and a NOR gate. FIG. 13 is a circuit diagram illustrating a configuration of an edge sampler 2ee in a fifth modification example of the embodiment.

The edge sampler 2ee includes the latch circuit 522 instead of the latch circuit 422 of the fourth modification example (see FIG. 12).

The latch circuit 522 of the present fifth modification example includes a logic gate 522g and a logic gate 522h instead of the logic gate 422g and the logic gate 422h of the fourth modification example (see FIG. 12). The logic gate 522g includes a NAND gate NA11. The logic gate 522h includes a NAND gate NA12.

The NAND gate NA11 is electrically connected between the lines L1 and L17 and the NOR gate NO1. The NAND gate NA11 has a first input node electrically connected to the input node 122a, a second input node electrically connected to the input node 322i, and an output node electrically connected to the first input node of the NOR gate NO1.

The NAND gate NA12 is electrically connected between the lines L2 and L17 and the NOR gate NO2. The NAND gate NA12 has a first input node electrically connected to the input node 122b, a second input node electrically connected to the input node 322i, and an output node electrically connected to the first input node of the NOR gate NO2.

Further, when the enable signal EN received from the control circuit 3 is at a non-active level (for example, L level), the operations of the latch circuit 522 and the offset adjustment circuits 423 and 424 each become a hold operation of holding a state, and when the enable signal EN is at an active level (for example, H level), the operations of the latch circuit 522 and the offset adjustment circuits 423 and 424 are the same as the operations of the second modification example illustrated in FIG. 10.

In this way, even with the configuration illustrated in FIG. 13, the offset components appearing at the output nodes 21f and 21g of the comparator 21 are all offset components corresponding to the difference between the L level and the H level, and as shown in Expressions 8 and 9, the offset components can be equal to each other.

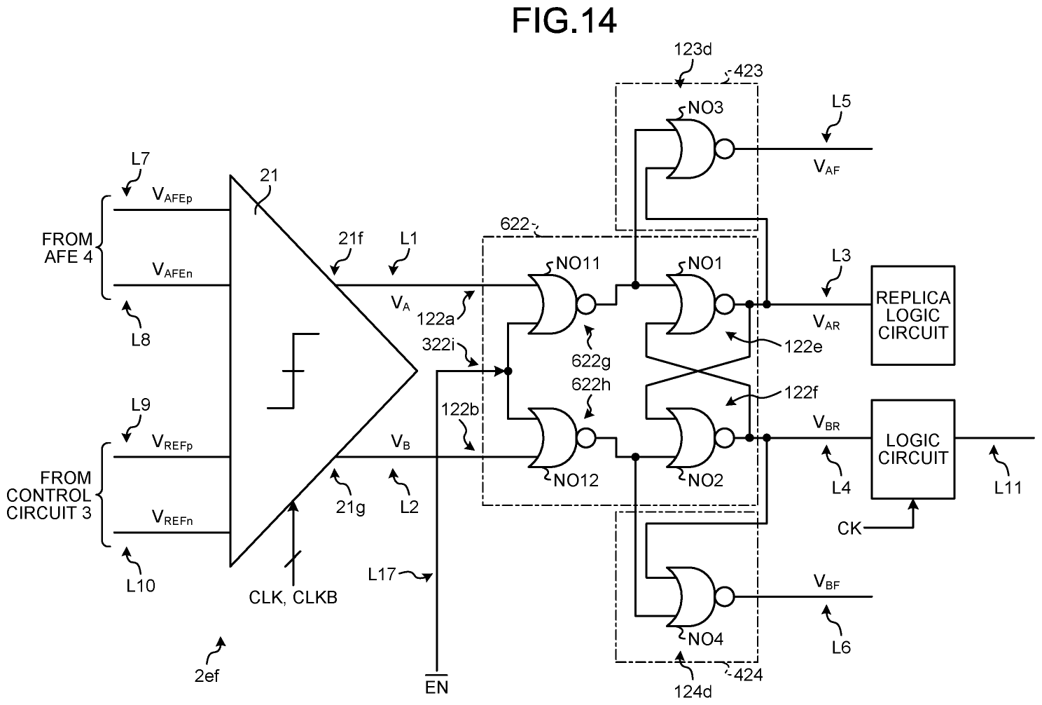

Alternatively, as illustrated in FIG. 14, a latch circuit 622 may be a gated S⁻R⁻ latch circuit including a NOR gate. FIG. 14 is a circuit diagram illustrating a configuration of an edge sampler 2ef in a sixth modification example of the embodiment.

The edge sampler 2ef of the present sixth modification example includes the latch circuit 622 instead of the latch circuit 422 of the fourth modification example (see FIG. 12).

The latch circuit 622 includes a logic gate 622g and a logic gate 622h instead of the logic gate 422g and the logic gate 422h of the fourth modification example (see FIG. 12). The logic gate 622g includes a NOR gate NO11. The logic gate 622h includes a NOR gate NO12. The input node 322i receives an enable signal EN⁻ from the control circuit 3 via the line L17.

The NOR gate NO11 is electrically connected between the lines L1 and L17 and the NOR gate NO1. The NOR gate NO11 has a first input node electrically connected to the input node 122a, a second input node electrically connected to the input node 322i, and an output node electrically connected to the first input node of the NOR gate NO1.

The NOR gate NO12 is electrically connected between the lines L2 and L17 and the NOR gate NO2. The NOR gate NO12 has a first input node electrically connected to the input node 122b, a second input node electrically connected to the input node 322i, and an output node electrically connected to the first input node of the NOR gate NO2.

Further, when the enable signal EN⁻ received from the control circuit 3 is at a non-active level (for example, H level), the operations of the latch circuit 622 and the offset adjustment circuits 423 and 424 each become a hold operation of holding a state, and when the enable signal EN⁻ is at an active level (for example, L level), the operations of the latch circuit 622 and the offset adjustment circuits 423 and 424 are the same as the operations of the second modification example illustrated in FIG. 10.

In this way, even with the configuration illustrated in FIG. 14, the offset components appearing at the output nodes 21f and 21g of the comparator 21 are all offset components corresponding to the difference between the L level and the H level, and as shown in Expressions 8 and 9, the offset components can be equal to each other.

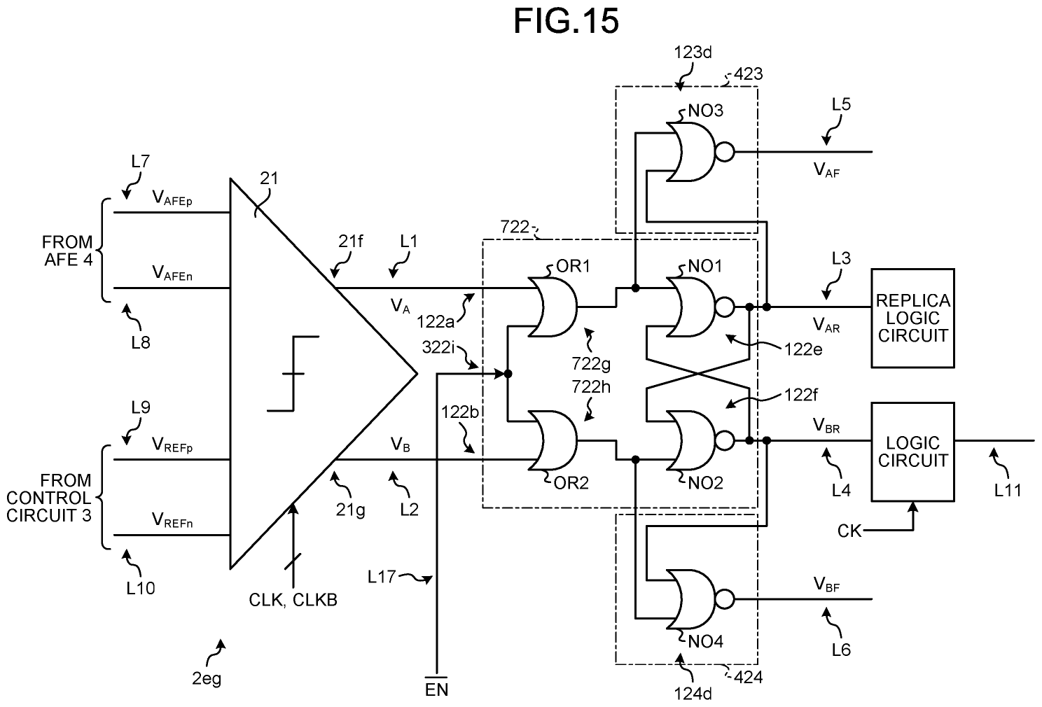

Alternatively, as illustrated in FIG. 15, a latch circuit 722 may be a gated S⁻R⁻ latch circuit including an OR gate and a NOR gate. FIG. 15 is a circuit diagram illustrating a configuration of an edge sampler 2eg in a seventh modification example of the embodiment.

The edge sampler 2eg of the present seventh modification example includes the latch circuit 722 instead of the latch circuit 422 of the fourth modification example (see FIG. 12).

The latch circuit 722 includes a logic gate 722g and a logic gate 722h instead of the logic gate 422g and the logic gate 422h of the fourth modification example (see FIG. 12). The logic gate 722g includes an OR gate OR1. The logic gate 722h includes an OR gate OR2.

The OR gate OR1 is electrically connected between the lines L1 and L17 and the NOR gate NO1. The OR gate OR1 has a first input node electrically connected to the input node 122a, a second input node electrically connected to the input node 322i, and an output node electrically connected to the first input node of the NOR gate NO1.

The OR gate OR2 is electrically connected between the lines L2 and L17 and the NOR gate NO2. The OR gate OR2 has a first input node electrically connected to the input node 122b, a second input node electrically connected to the input node 322i, and an output node electrically connected to the first input node of the NOR gate NO2.

Further, when the enable signal EN⁻ received from the control circuit 3 is at a non-active level (for example, H level), the operations of the latch circuit 722 and the offset adjustment circuits 423 and 424 each become a hold operation of holding a state, and when the enable signal EN⁻ is at an active level (for example, L level), the operations of the latch circuit 722 and the offset adjustment circuits 423 and 424 are the same as the operations of the first modification example illustrated in FIG. 8.

In this way, even with the configuration illustrated in FIG. 15, the offset components appearing at the output nodes 21f and 21g of the comparator 21 are all offset components corresponding to the difference between the L level and the H level, and as shown in Expressions 8 and 9, the offset components can be equal to each other.

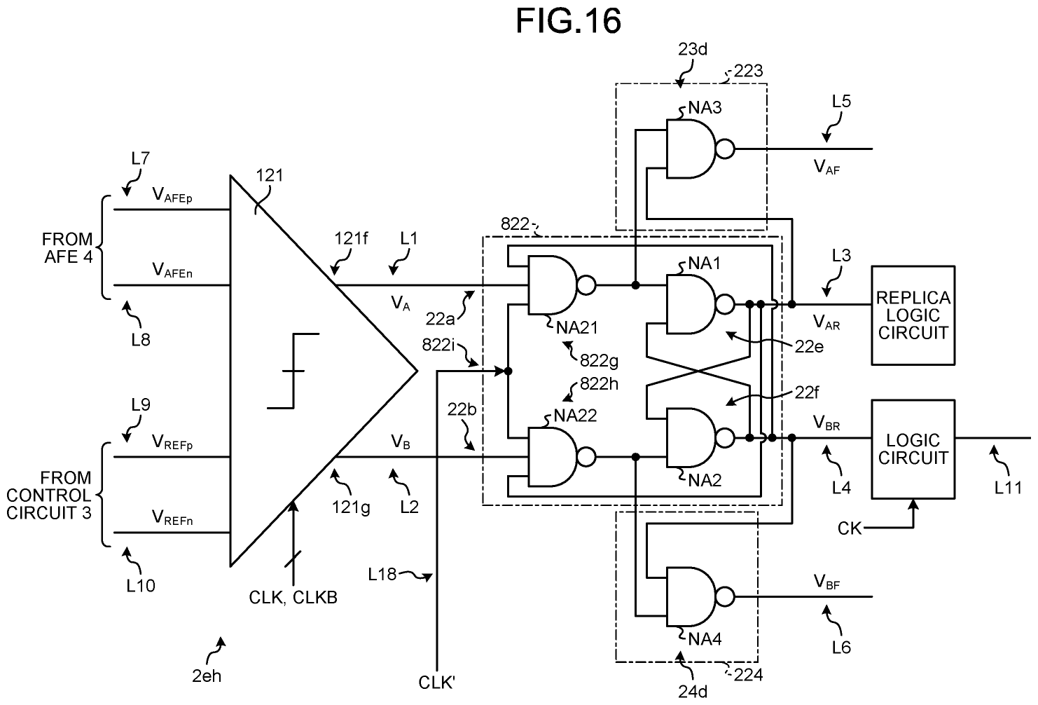

Alternatively, as illustrated in FIG. 16, a latch circuit 822 may be a JK latch circuit. FIG. 16 is a circuit diagram illustrating a configuration of an edge sampler 2eh in an eighth modification example of the embodiment.

The edge sampler 2eh of the present eighth modification example includes the latch circuit 822 instead of the latch circuit 222 of the second modification example (see FIG. 9), and further includes a line L18. The line L18 is electrically connected between the CDR circuit 202 (see FIGS. 1 and 2) and the latch circuit 822.

The latch circuit 822 includes logic gates 822g and 822h instead of the logic gates 222g and 222h of the second modification example (see FIG. 9), and further includes an input node 822i. The logic gate 822g includes a NAND gate NA21. The logic gate 822h includes a NAND gate NA22. The input node 822i is electrically connected to the CDR circuit 202 via the line L18. The input node 822i receives a clock CLK′ from the CDR circuit 202 via the line L18. The clock CLK′ may be the same as the clock CLK.

The NAND gate NA21 is electrically connected between the lines L1 and L18 and the NAND gate NA1. The NAND gate NA21 has a first input node electrically connected to the input node 22a, a second input node electrically connected to the input node 822i, a third input node electrically connected to the output node of the NAND gate NA2, and an output node electrically connected to the first input node of the NAND gate NA1.

The NAND gate NA22 is electrically connected between the lines L2 and L18 and the NAND gate NA2. The NAND gate NA22 has a first input node electrically connected to the input node 22b, a second input node electrically connected to the input node 822i, a third input node electrically connected to the output node of the NAND gate NA1, and an output node electrically connected to the first input node of the NAND gate NA2.

Further, during the period in which the clock CLK′ received from the control circuit 3 is at the L level, the operations of the latch circuit 822 and the offset adjustment circuits 223 and 224 each become a hold operation of holding a state, and during the period in which the clock CLK′ is at the H level, the set operation and the reset operation of the latch circuit 822 and the offset adjustment circuits 223 and 224 are the same as the operations of the second modification example illustrated in FIG. 10.

Note that, “Forbidden” illustrated in FIG. 10 is replaced with a toggle operation in which the latch circuit 822 inverts the input logic level, but the illustration and description thereof are omitted.

In this way, even with the configuration illustrated in FIG. 16, the offset components appearing at the output nodes 121f and 121g of the comparator 121 are all offset components corresponding to the difference between the L level and the H level, and as shown in Expressions 8 and 9, the offset components can be equal to each other.

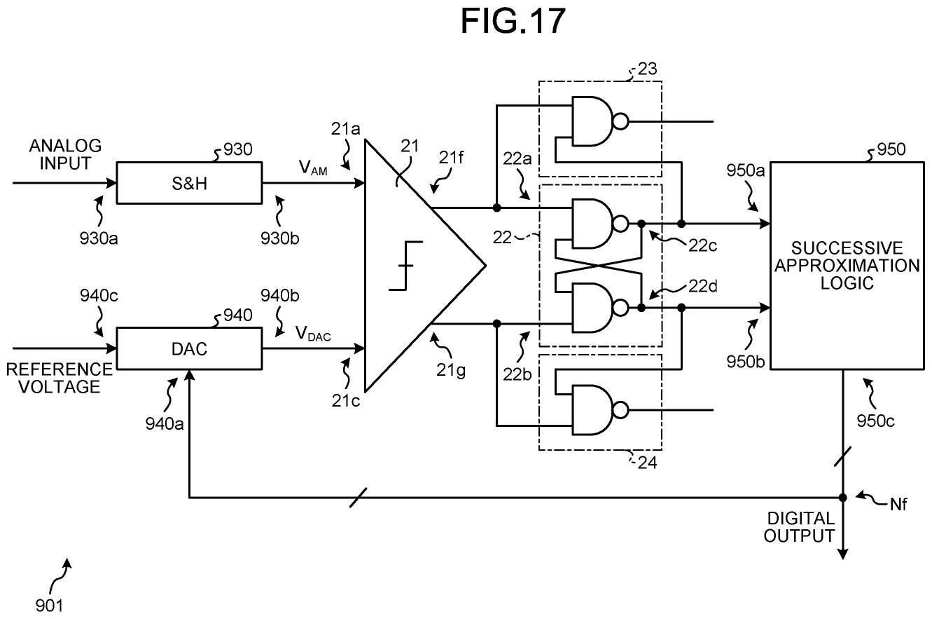

Further, the latch circuit and the offset adjustment circuits in the embodiment and the first to eighth modification examples thereof may be applied to another semiconductor integrated circuit instead of the semiconductor integrated circuit including the edge sampler. The latch circuit and the offset adjustment circuits in the embodiment and the first to eighth modification examples thereof may be applied to, for example, a successive approximation AD conversion circuit as illustrated in FIG. 17. FIG. 17 is a diagram illustrating a configuration of another semiconductor integrated circuit (successive approximation AD conversion circuit) 901 to which the latch circuit and the offset adjustment circuits in the embodiment and the first to eighth modification examples thereof are applied. FIG. 17 illustrates a case where the latch circuit 22 and the offset adjustment circuits 23 and 24 in the embodiment are applied to the semiconductor integrated circuit 901.

The semiconductor integrated circuit (successive approximation AD conversion circuit) 901 performs AD conversion on an analog input signal to generate a digital signal, and outputs the generated digital signal. The semiconductor integrated circuit 901 includes a sample hold (S & H) circuit 930, a comparator 21, a latch circuit 22, an offset adjustment circuit 23, an offset adjustment circuit 24, a successive approximation logic circuit 950, and a DA converter (DAC) 940.

The configurations and connection structures of the comparator 21, the latch circuit 22, the offset adjustment circuit 23, and the offset adjustment circuit 24 are the same as those of the comparator 21, the latch circuit 22, the offset adjustment circuit 23, and the offset adjustment circuit 24 in the embodiment. The comparator 21 is electrically connected between the S & H circuit 930 and the DAC 940, and the latch circuit 22, the offset adjustment circuit 23, and the offset adjustment circuit 24. The successive approximation logic circuit 950 is electrically connected between the latch circuit 22, the offset adjustment circuit 23, and the offset adjustment circuit 24, and a feedback node Nf.

An output node 930b of the S & H circuit 930 is electrically connected to an input node 21a of the comparator 21. An input node 940a of the DAC 940 is electrically connected to the feedback node Nf. An output node 940b of the DAC 940 is electrically connected to an input node 21c of the comparator 21. An output node 22c of the latch circuit 22 is electrically connected to an input node 950a of the successive approximation logic circuit 950. An output node 22d of the latch circuit 22 is electrically connected to an input node 950b of the successive approximation logic circuit 950. An output node 950c of the successive approximation logic circuit 950 is electrically connected to the feedback node Nf.

The S & H circuit 930 samples an analog input received at an input node 930a in synchronization with a sampling clock, and supplies the sampling result to the comparator 21 as an analog monitor value V_{AM}. The DAC 940 performs DA conversion on a digital output received at the input node 940a according to a reference voltage received at an input node 940c, and supplies the conversion result to the comparator 21 as a reference value V_{DAC}. The comparator 21 compares the analog monitor value V_{AM} with the reference value V_{DAC}, and supplies the comparison result to the successive approximation logic circuit 950 via the latch circuit 22. The successive approximation logic circuit 950 includes a shift register, and inputs the comparison result to the shift register. The successive approximation logic circuit 950 shifts the comparison result in the shift register one stage at a time in synchronization with a predetermined clock. The successive approximation logic circuit 950 supplies the output value from each stage register at a predetermined timing to the feedback node Nf as a digital output. The digital output supplied to the feedback node Nf is output to the outside and fed back to the DAC 940.

In this way, in the configuration illustrated in FIG. 17, as in the embodiment, the pair of differential signals can be optimized, and the hysteresis of the comparator 21 can be relaxed. Therefore, the indefinite value included in the digital output can be reduced, and the number of effective bits of the digital output with respect to the analog input can be easily increased.

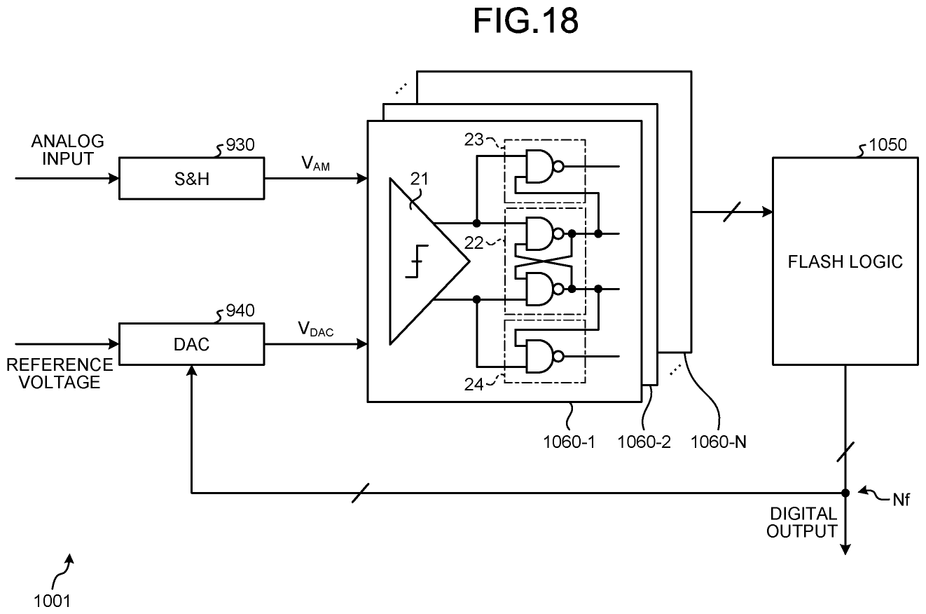

Further, the latch circuit and the offset adjustment circuits in the embodiment and the first to eighth modification examples thereof may be applied to an AD conversion circuit other than the successive approximation AD conversion circuit. For example, they may be applied to a flash semiconductor integrated circuit 1001 as illustrated in FIG. 18. FIG. 18 is a diagram illustrating a configuration of still another semiconductor integrated circuit (flash AD conversion circuit) 1001 to which the latch circuit and the offset adjustment circuits in the embodiment and the first to eighth modification examples thereof are applied. FIG. 18 illustrates a case where the latch circuit 22 and the offset adjustment circuits 23 and 24 in the embodiment are applied to the semiconductor integrated circuit 1001.

The semiconductor integrated circuit (flash AD conversion circuit) 1001 is different from the semiconductor integrated circuit (successive approximation AD conversion circuit) 901 in the following points. The semiconductor integrated circuit 1001 includes a flash logic circuit 1050 instead of the successive approximation logic circuit 950 (see FIG. 17). The semiconductor integrated circuit 1001 includes N circuit blocks 1060-1 to 1060-N each including a comparator 21, a latch circuit 22, an offset adjustment circuit 23, and an offset adjustment circuit 24 (N is an integer of 2 or more). The N circuit blocks 1060-1 to 1060-N are electrically connected in parallel between the S & H circuit 930 and the DAC 940, and the flash logic circuit 1050.

The analog monitor value V_{AM} from the S & H circuit 930 is converted into different values (analog monitor-divided voltage values) by, for example, dividing the voltage into stepwise values with a resistance ladder (not illustrated) and is supplied to each circuit block 1060 in parallel. The comparator 21 in each circuit block 1060 compares the analog monitor-divided voltage value with the reference value V_{DAC} from the DAC 940, and supplies the comparison result to the flash logic circuit 1050 via the latch circuit 22 in parallel. The flash logic circuit 1050 combines the comparison results output from the circuit blocks 1060 and supplies the combined result to the feedback node Nf as a digital output. The digital output supplied to the feedback node Nf is output to the outside and fed back to the DAC 940.

Bubble error rejection of the flash semiconductor integrated circuit 1001 is considered. A bubble error may occur in the comparator 21 of each circuit block 1060. The bubble error is a phenomenon in which, for example, 1 is mixed while 0 is continued or 0 is entered while 1 is continued, such as 00100001111101, with respect to a correct answer of 00000001111111 from the lower bits. This mixed value is called a bubble, and is caused by a circuit band, crosstalk, noise, or the like, and the hysteresis of the comparator 21 is included in one of the causes.

Although a certain bubble removal is possible by the correction method based on the majority of the previous and subsequent data, called bubble error correction, it is difficult to completely erase the bubble, and suppression of the bubble itself is desired. Therefore, bubble errors can be reduced by applying the present technology.

In this way, in the configuration illustrated in FIG. 18, as in the embodiment, the pair of differential signals can be optimized, and the hysteresis of the comparator 21 can be relaxed. Therefore, the indefinite value and the bubble error value included in the digital output can be reduced, and the number of effective bits of the digital output with respect to the analog input can be easily increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
a first line;
a second line forming a differential pair with the first line;
a third line;
a fourth line forming a differential pair with the third line;
a latch circuit comprising a first input node electrically connected to the first line, a second input node electrically connected to the second line, a first output node electrically connected to the third line, and a second output node electrically connected to the fourth line;
a first offset adjustment circuit electrically connected between the first line and the third line; and
a second offset adjustment circuit having a circuit configuration equivalent to the first offset adjustment circuit and electrically connected between the second line and the fourth line.

2. The semiconductor integrated circuit according to claim 1,
wherein the latch circuit comprises
a first logic gate, and
a second logic gate having a configuration equivalent to that of the first logic gate,
the first offset adjustment circuit includes a third logic gate having a configuration equivalent to that of the first logic gate, and
the second offset adjustment circuit includes a fourth logic gate having a configuration equivalent to that of the second logic gate.

3. The semiconductor integrated circuit according to claim 2,
wherein the first logic gate includes a first NAND gate having a first input node electrically connected to the first line, a second input node electrically connected to the fourth line, and an output node electrically connected to the third line,
the second logic gate includes a second NAND gate having a first input node electrically connected to the second line, a second input node electrically connected to the third line, and an output node electrically connected to the fourth line,
the third logic gate includes a third NAND gate having a first input node electrically connected to the first line, a second input node electrically connected to the third line, and an output node electrically connected to a fifth line different from the first line to the fourth line, and
the fourth logic gate includes a fourth NAND gate having a first input node electrically connected to the second line, a second input node electrically connected to the fourth line, and an output node electrically connected to a sixth line different from the first line to the fifth line.

4. The semiconductor integrated circuit according to claim 3,
wherein the fifth line is in an open state that is not directly connected to any of the first line to the fourth line, and
the sixth line is in an open state that is not directly connected to any of the first line to the fourth line.

5. The semiconductor integrated circuit according to claim 2,
wherein the first logic gate includes a first NOR gate having a first input node electrically connected to the first line, a second input node electrically connected to the fourth line, and an output node electrically connected to the third line,
the second logic gate includes a second NOR gate having a first input node electrically connected to the second line, a second input node electrically connected to the third line, and an output node electrically connected to the fourth line,
the third logic gate includes a third NOR gate having a first input node electrically connected to the first line, a second input node electrically connected to the third line, and an output node electrically connected to a fifth line different from the first line to the fourth line, and
the fourth logic gate includes a fourth NOR gate having a first input node electrically connected to the second line, a second input node electrically connected to the fourth line, and an output node electrically connected to a sixth line different from the first line to the fifth line.

6. The semiconductor integrated circuit according to claim 5,
wherein the fifth line is in an open state that is not directly connected to any of the first line to the fourth line, and
the sixth line is in an open state that is not directly connected to any of the first line to the fourth line.

7. The semiconductor integrated circuit according to claim 2,
wherein the latch circuit further includes
a fifth logic gate comprising an output node electrically connected to an input node of the first logic gate and an input node of the third logic gate, and an input node electrically connected to the first input node of the latch circuit, and
a sixth logic gate comprising an output node electrically connected to an input node of the second logic gate and an input node of the fourth logic gate, and an input node electrically connected to the second input node of the latch circuit.

8. The semiconductor integrated circuit according to claim 1, further comprising:
a comparison circuit having a first output node electrically connected to the first line and a second output node electrically connected to the second line.

9. The semiconductor integrated circuit according to claim 8,
wherein the comparison circuit is configured to perform a reset operation in a first period in which a clock signal is at a second level, and perform a sampling operation in a second period in which the clock signal is at a first level, and
the latch circuit is configured to perform a set operation according to a signal of the second level received via the first line and a signal of the first level received via the second line during the first period, perform a reset operation according to a signal of the first level received via the first line and a signal of the second level received via the second line during the first period, and perform a hold operation according to a signal of the first level received via the first line and a signal of the first level received via the second line during the second period.

10. The semiconductor integrated circuit according to claim 8,
wherein the comparison circuit is configured to perform a reset operation in a first period in which a clock signal is at a second level, and perform a sampling operation in a second period in which the clock signal is at a first level, and
the latch circuit is configured to perform a set operation according to a signal of the first level received via the first line and a signal of the second level received via the second line during the first period, perform a reset operation according to a signal of the second level received via the first line and a signal of the first level received via the second line during the first period, and perform a hold operation according to a signal of the first level received via the first line and a signal of the first level received via the second line during the second period.

11. The semiconductor integrated circuit according to claim 8, further comprising:
a seventh line;
an eighth line forming a differential pair with the seventh line; and
a receiving circuit having a first output node electrically connected to the seventh line and a second output node electrically connected to the eighth line,
wherein the comparison circuit further comprises a first input node electrically connected to the seventh line and a second input node electrically connected to the eighth line.

12. The semiconductor integrated circuit according to claim 1, further comprising:
a DA (Digital-to-Analog) conversion circuit having a first output node electrically connected to the first line and a second output node electrically connected to the second line.

13. A receiving device comprising:
a receiving node to which a wired transmission path is connected; and
a semiconductor integrated circuit to which the receiving node is electrically connected,
wherein the semiconductor integrated circuit comprises
a first line,
a second line forming a differential pair with the first line,
a third line,
a fourth line forming a differential pair with the third line,
a latch circuit comprising a first input node electrically connected to the first line, a second input node electrically connected to the second line, a first output node electrically connected to the third line, and a second output node electrically connected to the fourth line,
a first offset adjustment circuit electrically connected between the first line and the third line, and
a second offset adjustment circuit having a circuit configuration equivalent to the first offset adjustment circuit and electrically connected between the second line and the fourth line.

14. The receiving device according to claim 13,
wherein the latch circuit comprises
a first logic gate, and
a second logic gate having a configuration equivalent to that of the first logic gate,
the first offset adjustment circuit includes a third logic gate having a configuration equivalent to that of the first logic gate, and
the second offset adjustment circuit includes a fourth logic gate having a configuration equivalent to that of the second logic gate.

15. The receiving device according to claim 14,
wherein the first logic gate includes a first NAND gate having a first input node electrically connected to the first line, a second input node electrically connected to the fourth line, and an output node electrically connected to the third line,
the second logic gate includes a second NAND gate having a first input node electrically connected to the second line, a second input node electrically connected to the third line, and an output node electrically connected to the fourth line,
the third logic gate includes a third NAND gate having a first input node electrically connected to the first line, a second input node electrically connected to the third line, and an output node electrically connected to a fifth line different from the first line to the fourth line, and
the fourth logic gate includes a fourth NAND gate having a first input node electrically connected to the second line, a second input node electrically connected to the fourth line, and an output node electrically connected to a sixth line different from the first line to the fifth line.

16. The receiving device according to claim 15,
wherein the fifth line is in an open state that is not directly connected to any of the first line to the fourth line, and
the sixth line is in an open state that is not directly connected to any of the first line to the fourth line.

17. The receiving device according to claim 14,
wherein the first logic gate includes a first NOR gate having a first input node electrically connected to the first line, a second input node electrically connected to the fourth line, and an output node electrically connected to the third line,
the second logic gate includes a second NOR gate having a first input node electrically connected to the second line, a second input node electrically connected to the third line, and an output node electrically connected to the fourth line,
the third logic gate includes a third NOR gate having a first input node electrically connected to the first line, a second input node electrically connected to the third line, and an output node electrically connected to a fifth line different from the first line to the fourth line, and
the fourth logic gate includes a fourth NOR gate having a first input node electrically connected to the second line, a second input node electrically connected to the fourth line, and an output node electrically connected to a sixth line different from the first line to the fifth line.

18. The receiving device according to claim 14,
wherein the latch circuit further includes
a fifth logic gate comprising an output node electrically connected to an input node of the first logic gate and an input node of the third logic gate, and an input node electrically connected to the first input node of the latch circuit, and
a sixth logic gate comprising an output node electrically connected to an input node of the second logic gate and an input node of the third logic gate, and an input node electrically connected to the first input node of the latch circuit.

19. The receiving device according to claim 13,
wherein the semiconductor integrated circuit further includes a comparison circuit having a first output node electrically connected to the first line and a second output node electrically connected to the second line.

20. The receiving device according to claim 19,
wherein the semiconductor integrated circuit further includes
a seventh line,
an eighth line forming a differential pair with the seventh line, and
a receiving circuit having a first output node electrically connected to the seventh line and a second output node electrically connected to the eighth line, and wherein
the comparison circuit further comprises a first input node electrically connected to the seventh line and a second input node electrically connected to the eighth line.
